(19) United States
(12) Patent Application Publication
(10) Pub. No.: US 2026/0280409 A1
(43) Pub. Date: Sep. 17, 2026

(54) ELECTRONIC CIRCUITRY, POWER CONVERTER, AND POWER CONVERSION APPARATUS

(71) Applicant: Kabushiki Kaisha Toshiba, Kawasaki-shi (JP)

(72) Inventors: Koutaro MIYAZAKI, Taito Tokyo (JP); Hiroaki ISHIHARA, Yokohama Kanagawa (JP); Shusuke KAWAI, Fujisawa Kanagawa (JP); Takeshi UENO, Kawasaki Kanagawa (JP); Kohei HORII, Kawasaki Kanagawa (JP); Yuto BUSHIMATA, Kawasaki Kanagawa (JP)

(21) Appl. No.: 19/529,821

(22) Filed: Feb. 4, 2026

(30) Foreign Application Priority Data
Mar. 13, 2025 (JP) 2025-040670

(51) Int. Cl. H02M 1/08; H02M 7/5387; H03K 5/1534; H03K 17/16

(52) U.S. Cl. CPC H02M 1/08; H02M 7/53875; H03K 5/1534; H03K 17/166; H03K 2217/0027

(57) ABSTRACT

According to one embodiment, an electronic circuitry includes an arithmetic circuit performing an operation based on a physical quantity corresponding to a time rate of change of an output current of a switching element controlled in accordance with a control signal instructing turn-on or turn-off; a timing detection circuit detecting, based on a calculation result of the arithmetic circuit, a first timing and a second timing later than the first timing in a transition period of the turn-on or the turn-off; a current supply circuit supplying a drive current to the switching element in accordance with a command value of the drive current to be supplied to the switching element; and a controller switching a drive current value specified by the command value to a first current value correspondingly to the first timing, and switching the drive current value to a second current value correspondingly to the second timing.

### CROSS REFERENCE TO RELATED APPLICATIONS

This application is based upon and claims the benefit of priority from the prior Japanese Patent Application No. 2025-040670, filed on Mar. 13, 2025, the entire contents of which are incorporated herein by reference.

### FIELD

Embodiments described herein relate to an electronic circuitry, a power converter, and a power conversion apparatus.

### BACKGROUND

A switching element used in a power circuit, an inverter, or the like exhibits a smaller power loss the shorter the transition time in a turn-on operation or a turn-off operation. However, electromagnetic noise (electro-magnetic interference (EMI)) is generated in a turn-on operation or a turn-off operation of the switching element, and the magnitude of EMI increases as the transition time decreases. In other words, the power loss and EMI have a trade-off relation. In order to adjust such trade-off, controlling the magnitude of drive current supplied during a transition period in a turn-on operation or a turn-off operation of the switching element has been considered.

The transition period in a turn-on operation of the switching element is shorter as the drive current is larger. On the other hand, the surge (current surge) of output current occurs in a turn-on operation of the switching element, and the magnitude of the current surge is larger as the drive current is larger.

### BRIEF DESCRIPTION OF THE DRAWINGS

FIG. 1 is a diagram illustrating the configuration of a half-bridge inverter according to Embodiment 1;

FIG. 2 is a diagram illustrating a detailed configuration of a drive circuit of Embodiment 1;

FIG. 3 is a diagram illustrating a detailed configuration of a turn-on current command circuit of Embodiment 1;

FIG. 4 is a diagram for description of an operation of a switching element of Embodiment 1 in a turn-on operation;

FIG. 5 is a diagram for description of an operation of the switching element of Embodiment 1 in a turn-on operation;

FIG. 6 is a diagram illustrating a detailed configuration of a turn-on current command circuit of Embodiment 2;

FIG. 7 is a diagram for description of an operation of a switching element of Embodiment 2 in a turn-on operation;

FIG. 8 is a diagram for description of an operation of the switching element of Embodiment 2 in a turn-on operation;

FIG. 9 is a diagram illustrating a detailed configuration of a turn-on current command circuit of Embodiment 3;

FIG. 10 is a diagram for description of an operation of a switching element of Embodiment 3 in a turn-on operation;

FIG. 11 is a diagram for description of an operation of the switching element of Embodiment 3 in a turn-on operation;

FIG. 12 is a diagram illustrating a detailed configuration of a turn-on current command circuit of Embodiment 4;

FIG. 13 is a diagram illustrating a detailed configuration of a turn-on current command circuit of Embodiment 5;

FIG. 14 is a diagram illustrating a detailed configuration of a turn-on current command circuit of Embodiment 6;

FIG. 15 is a diagram illustrating a detailed configuration of a turn-on current command circuit of Embodiment 7;

FIG. 16 is a diagram for description of an operation of a switching element of Embodiment 7 in a turn-on operation;

FIG. 17 is a diagram for description of an operation of the switching element of Embodiment 7 in a turn-on operation;

FIG. 18 is a diagram illustrating a detailed configuration of a turn-on current command circuit of Embodiment 8;

FIG. 19 is a diagram illustrating a detailed configuration of a turn-on current command circuit of Embodiment 9;

FIG. 20 is a diagram for description of an operation of a switching element of Embodiment 9 in a turn-on operation;

FIG. 21 is a diagram illustrating a detailed configuration of a turn-on current command circuit of Embodiment 10;

FIG. 22 is a diagram illustrating a detailed configuration of a drive circuit of Embodiment 11;

FIG. 23 is a diagram illustrating a detailed configuration of a turn-off current command circuit of Embodiment 11;

FIG. 24 is a diagram for description of an operation of a switching element of Embodiment 11 in a turn-off operation; and

FIG. 25 is a diagram illustrating the configuration of a three-phase inverter according to Embodiment 12.

### DETAILED DESCRIPTION

According to one embodiment, an electronic circuitry includes: an arithmetic circuit configured to perform an operation based on a physical quantity corresponding to a time rate of change of an output current of a switching element controlled in accordance with a control signal instructing turn-on or turn-off; a timing detection circuit configured to detect, based on a calculation result of the arithmetic circuit, a first timing and a second timing later than the first timing in a transition period of the turn-on or the turn-off; a current supply circuit configured to supply a drive current to the switching element in accordance with a command value of the drive current to be supplied to the switching element; and a controller configured to switch a drive current value specified by the command value to a first current value in response to the first timing, and switch the drive current value to a second current value in response to the second timing.

According to one embodiment, a power converter includes: a half-bridge circuit including two switching elements; and a first drive circuit and a second drive circuit configured to respectively control the two switching elements in accordance with a control signal instructing turn-on or turn-off. Each of the first drive circuit and the second drive circuit includes: an arithmetic circuit configured to perform an operation based on a physical quantity corresponding to a time rate of change of an output current of the switching element controlled by the drive circuit; a timing detection circuit configured to detect, based on a calculation result of the arithmetic circuit, a first timing and a second timing later than the first timing in a transition period of the turn-on or the turn-off; a current supply circuit configured to supply a drive current to the switching element in accordance with a command value of the drive current to be supplied to the switching element; and a controller configured to switch a drive current value specified by the command value to a first current value in response to the first timing, and switch the drive current value to a second current value in response to the second timing.

The present embodiments will be described below with reference to the accompanying drawings. In the drawings, identical or corresponding elements are denoted by the same reference signs, and detailed description thereof will not be repeated as appropriate.

### Embodiment 1

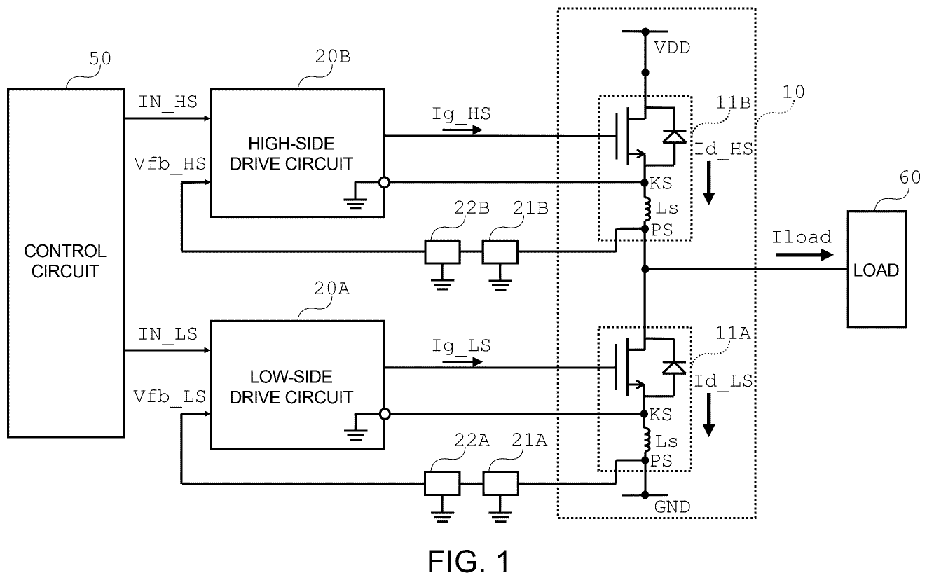

FIG. 1 is a diagram illustrating the configuration of a half-bridge inverter that is a power converter according to Embodiment 1. The half-bridge inverter includes a half-bridge circuit 10, a low-side drive circuit 20A, a high-side drive circuit 20B, and a control circuit 50. A load 60 is connected to an output of the half-bridge inverter.

The half-bridge circuit 10 includes a low-side switching element 11A and a high-side switching element 11B, which are controlled to be driven in accordance with control signals supplied from the control circuit 50. For example, the switching elements 11A and 11B may be N-channel metal oxide semiconductor field effect transistors (MOSFETs). In this case, the switching elements 11A and 11B may each include a Kelvin source terminal (KS) in addition to gate, drain, and power source (PS) terminals. Hereinafter, the switching elements 11A and 11B are described as including the Kelvin source terminal (KS), but the technical applicable range of the present embodiment is not limited to MOSFETs including the Kelvin source terminal (KS).

Alternatively, the switching elements 11A and 11B may be N-channel insulated gate bipolar transistors (IGBTs). In this case, the switching elements 11A and 11B may each include a Kelvin emitter terminal (KE) in addition to gate, collector, and power emitter (PE) terminals. However, the technical applicable range of the present embodiment is not limited to IGBTs including the Kelvin emitter terminal (KE).

The drain of the low-side switching element 11A is connected to the power source PS of the high-side switching element 11B. The Kelvin source KS of the switching element 11A is connected to a ground of the low-side drive circuit 20A. A parasitic inductance Ls (low-side parasitic inductance Ls) is included between the Kelvin source KS and the power source PS of the switching element 11A. The power source PS of the switching element 11A is connected to a ground GND of the half-bridge inverter.

The power source PS of the switching element 11A is connected to the low-side drive circuit 20A through an attenuator 21A and a DC bias circuit 22A. The attenuator 21A and the DC bias circuit 22A are connected to the same ground as the low-side drive circuit 20A.

The drain of the high-side switching element 11B is connected to a power voltage VDD of the half-bridge inverter. The Kelvin source KS of the switching element 11B is connected to a ground of the high-side drive circuit 20B. A parasitic inductance Ls (high-side parasitic inductance Ls) is included between the Kelvin source KS and the power source PS of the switching element 11B.

The power source PS of the switching element 11B is connected to the high-side drive circuit 20B through an attenuator 21B and a DC bias circuit 22B. The attenuator 21B and the DC bias circuit 22B are connected to the same ground as the high-side drive circuit 20B.

In the present embodiment, the grounds of the low-side drive circuit 20A and the high-side drive circuit 20B are separated from the ground GND of the half-bridge inverter. The switching elements 11A and 11B and the drive circuits 20A and 20B may be included in separate IC packages or may be included in the same IC package. The switching elements 11A and 11B and the drive circuits 20A and 20B may be mounted on different semiconductor substrates or may be mounted on the same semiconductor substrate.

The direction of a current (load current) Iload supplied from the half-bridge inverter to the load 60 is defined such that a direction in which the current flows from the half-bridge circuit 10 to the load 60 is positive, and a direction in which the current flows from the load 60 to the half-bridge circuit 10 is negative. However, this definition may be reversed.

The low-side drive circuit 20A supplies a gate current (low-side drive current) Ig_LS to the low-side switching element 11A in accordance with a low-side control signal IN_LS supplied from the control circuit 50. Specifically, when the low-side control signal IN_LS is “Hi” (for example, +5 V), the drive current Ig_LS flows from the drive circuit 20A toward the gate of the switching element 11A. In other words, the positive drive current Ig_LS is supplied from the drive circuit 20A to the switching element 11A. On the other hand, when the low-side control signal IN_LS is “Lo” (for example, 0 V), the drive current Ig_LS flows from the gate of the switching element 11A toward the drive circuit 20A. In other words, the negative drive current Ig_LS is supplied from the drive circuit 20A to the switching element 11A.

Similarly, the high-side drive circuit 20B supplies a gate current (high-side drive current) Ig_HS to the high-side switching element 11B in accordance with a high-side control signal IN_HS supplied from the control circuit 50. Specifically, when the high-side control signal IN_HS is “Hi” (for example, +5 V), the drive current Ig_HS flows from the drive circuit 20B toward the gate of the switching element 11B. In other words, the positive drive current Ig_HS is supplied from the drive circuit 20B to the switching element 11B. On the other hand, when the high-side control signal IN_HS is “Lo” (for example, 0 V), the drive current Ig_HS flows from the gate of the switching element 11B toward the drive circuit 20B. In other words, the negative drive current Ig_HS is supplied from the drive circuit 20B to the switching element 11B.

The control circuit 50 supplies the low-side control signal IN_LS to the low-side drive circuit 20A, and supplies the high-side control signal IN_HS to the high-side drive circuit 20B. The load 60 is any electronic apparatus or electric apparatus that is driven by alternating-current power. For example, in a case where the load 60 is an alternating-current motor, the control circuit 50 supplies the PWM-modulated low-side control signal IN_LS to the low-side drive circuit 20A, and supplies the PWM-modulated high-side control signal IN_HS to the high-side drive circuit 20B. Alternatively, the half-bridge inverter may be mounted in a power source apparatus such as a PV inverter for photovoltaic power generation. In this case, an output of the half-bridge circuit 10 is connected to a power grid in place of the load 60.

The low-side attenuator 21A is constituted by, for example, capacitors or resistors connected in series, and outputs a voltage obtained by dividing the voltage of the power source PS of the switching element 11A at a predetermined ratio. Specifically, when the voltage of the power source PS of the switching element 11A is denoted by Vps, an output voltage Va of the attenuator 21A is expressed by Expression (1) below.

$$\begin{matrix}[ Math . 1 ] & \\ {V}_{a} = {a V}_{ps} & ( 1 )\end{matrix}$$

In Expression (1) above, “a” is the division scale of the attenuator 21A and is set to a predetermined value within a range of 0<a<1.

The low-side DC bias circuit 22A is constituted by, for example, resistors and a constant-voltage source, and outputs a voltage obtained by adding a predetermined bias voltage Vbias to the output voltage Va of the attenuator 21A. Accordingly, an output voltage Vb of the DC bias circuit 22A is expressed by Expression (2) below.

$$\begin{matrix}[ Math . 2 ] & \\ {V}_{b} = {V}_{a} + {V}_{bias} = {a V}_{ps} + {V}_{bias} & ( 2 )\end{matrix}$$

As described above, the Kelvin source KS of the switching element 11A is connected to the ground of the low-side drive circuit 20A. Thus, for the low-side drive circuit 20A, the voltage Vps of the power source PS of the switching element 11A is equal to a voltage VIs that occurs across both ends of the parasitic inductance Ls of the switching element 11A.

The attenuator 21A and the DC bias circuit 22A are connected to the same ground as the low-side drive circuit 20A. Accordingly, a voltage Vfb_LS input to the low-side drive circuit 20A through the attenuator 21A and the DC bias circuit 22A is expressed by Expression (3) below by using the voltage VIs (=Vps) that occurs across both ends of the parasitic inductance Ls of the switching element 11A.

$$\begin{matrix}[ Math . 3 ] & \\ {V}_{fb} \_LS = {a V}_{ls} + {V}_{bias} & ( 3 )\end{matrix}$$

The voltage VIs that occurs across both ends of the parasitic inductance Ls of the switching element 11A is caused by a change over time (a time rate of change) of a drain current (output current) Id_LS of the switching element 11A, and the following relational expression (4) holds between the voltage VIs and the drain current Id_LS.

$$\begin{matrix}[ Math . 4 ] & \\ {V}_{ls} = - {L}_{s} \frac{d ( {I}_{d \_} LS )}{dt} & ( 4 )\end{matrix}$$

The following relational expression (5) is obtained by substituting Expression (4) into Expression (3).

$$\begin{matrix}[ Math . 5 ] & \\ {V}_{fb} \_LS = - {aL}_{s} \frac{d ( {I}_{d \_} LS )}{dt} + {V}_{bias} & ( 5 )\end{matrix}$$

Expression (5) above indicates that the voltage Vfb_LS input to the low-side drive circuit 20A is a physical quantity corresponding to a change over time (a time rate of change) of the output current Id_LS of the switching element 11A. In other words, the low-side drive circuit 20A can acquire the voltage Vfb_LS as a physical quantity corresponding to a change over time (a time rate of change) of the output current Id_LS of the switching element 11A.

However, a physical quantity corresponding to a change over time (a time rate of change) of the output current Id_LS of the switching element 11A is not limited thereto. For example, a physical quantity corresponding to a change over time (a time rate of change) of the output current Id_LS may be acquired by connecting a shunt resistor to the power source PS of the switching element 11A and passing a voltage that occurs across both ends of the shunt resistor through a high-pass filter that functions as a differentiator.

The above-described discussion similarly applies to the high-side drive circuit 20B. Accordingly, the high-side drive circuit 20B can acquire a voltage Vfb_HS as a physical quantity corresponding to a change over time (a time rate of change) of an output current Id_HS of the switching element 11B.

### Configuration of Drive Circuit

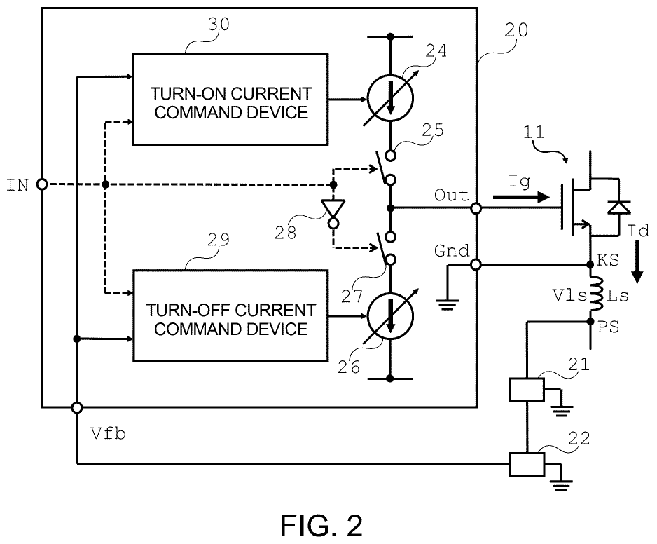

FIG. 2 is a diagram illustrating a detailed configuration of a drive circuit 20 according to Embodiment 1. Note that the low-side drive circuit 20A and the high-side drive circuit 20B have the same configuration, and thus hereinafter, are collectively referred to as the drive circuit 20 and described in a unified manner. This also applies to other constituent components. In addition, signals such as the control signals IN_LS and IN_HS are collectively referred to as a control signal IN or the like.

The drive circuit 20 includes a first variable current source 24, a first switch 25, a second variable current source 26, a second switch 27, a NOT gate 28, a turn-off current command circuit 29, and a turn-on current command circuit 30. The components 24 to 28 constitute a current supply circuit of the drive circuit 20.

The turn-off current command circuit 29 determines a command value of a drive current Ig_off to be supplied in a turn-off operation of a switching element 11, and outputs the command value to the second variable current source 26. The second variable current source 26 outputs a current in accordance with the command value input from the turn-off current command circuit 29. The second switch 27 is turned on only when the control signal IN is “Lo”. Accordingly, in a turn-off operation of the switching element 11, the drive circuit 20 outputs the drive current Ig_off in accordance with the command value specified by the turn-off current command circuit 29.

The turn-on current command circuit 30 controls a command value of a drive current Ig_on to be supplied in a turn-on operation so as to suppress the surge (current surge) of a drain current Id that occurs in a turn-on operation of the switching element 11. Specifically, the turn-on current command circuit 30 determines a command value of the drive current Ig_on based on a voltage Vfb corresponding to a change over time (a time rate of change) of an output current Id of the switching element 11, and outputs the command value to the first variable current source 24. The first variable current source 24 outputs a current in accordance with the command value input from the turn-on current command circuit 30. The first switch 25 is turned on only when the control signal IN is “Hi”. Accordingly, in a turn-on operation of the switching element 11, the drive circuit 20 outputs the drive current Ig_on in accordance with the command value specified by the turn-on current command circuit 30.

### Configuration of Turn-on Current Command Circuit

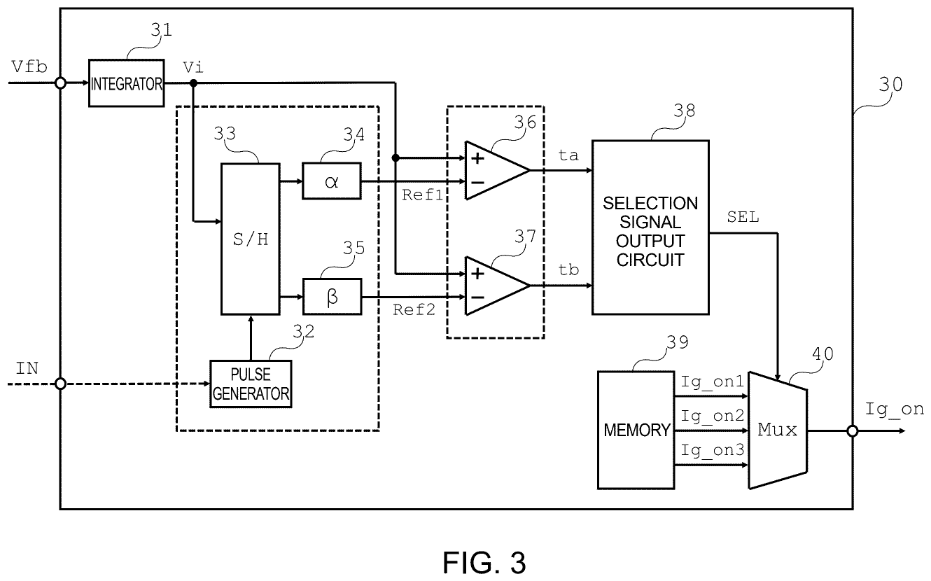

FIG. 3 is a diagram illustrating a detailed configuration of the turn-on current command circuit 30 according to Embodiment 1. The turn-on current command circuit 30 includes an integrator (arithmetic circuit) 31, a pulse generator 32, a sample-and-hold circuit 33, a first amplifier 34, a second amplifier 35, a first comparator 36, and a second comparator 37. The components 32 to 35 constitute a reference value generator of the turn-on current command circuit 30. The components 36 and 37 constitute a timing detection circuit of the turn-on current command circuit 30. The turn-on current command circuit 30 also includes a selection signal output circuit 38, a memory 39, and a multiplexer 40. The components 38 to 40 constitute a controller of the turn-on current command circuit 30.

The integrator 31 outputs a voltage Vi obtained by integrating the voltage Vfb. Since the voltage Vfb is a physical quantity corresponding to a change over time (a time rate of change) of the output current Id of the switching element 11, the output voltage Vi of the integrator 31 is a physical quantity corresponding to the output current Id of the switching element 11.

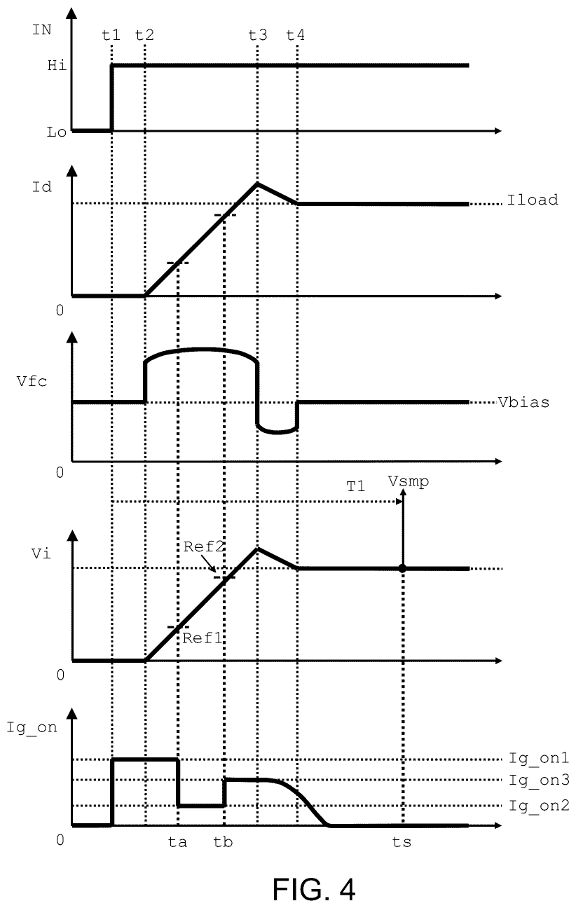

The pulse generator 32 outputs one clock pulse at a timing at which a predetermined time T1 has elapsed after the control signal IN changes from “Lo” to “Hi”. Although described later in detail with reference to FIG. 4, the predetermined time T1 is set to a time longer than a time from start of a turn-on operation at which the control signal IN changes from “Lo” to “Hi” to a time at which ringing of the drain current Id converges after completion of the turn-on operation and reaches a steady value, that is, a load current Iload.

The sample-and-hold circuit 33 samples the voltage Vi by using a clock pulse output from a clock generator 32 as a trigger. Accordingly, a hold voltage Vsmp of the sample-and-hold circuit 33 is a voltage corresponding to the steady value of the drain current Id after completion of a turn-on operation of the switching element 11, that is, the load current Iload. In other words, the sample-and-hold circuit 33 can acquire the voltage Vsmp as a physical quantity corresponding to the load current Iload.

The first amplifier 34 amplifies the hold voltage Vsmp of the sample-and-hold circuit 33 with a predetermined amplification factor α, thereby generating a first reference voltage Ref1 defined by Expression (6) below.

$$\begin{matrix}[ Math . 6 ] & \\ Ref 1 = {αV}_{smp} & ( 6 )\end{matrix}$$

In Expression (6) above, the amplification factor α is experimentally determined in advance so that the surge of the drain current Id, which occurs in a turn-on operation, is always sufficiently suppressed within a variation range of the load current Iload. In the present embodiment, a is set to a value within a range greater than zero and less than one. For example, a is set to approximately 0.1.

Similarly, the second amplifier 35 amplifies the hold voltage Vsmp of the sample-and-hold circuit 33 with a predetermined amplification factor β, thereby generating a second reference voltage Ref2 defined by Expression (7) below.

$$\begin{matrix}[ Math . 7 ] & \\ Ref 2 = {βV}_{smp} & ( 7 )\end{matrix}$$

In Expression (7) above, the amplification factor β is experimentally determined in advance so that the surge of the drain current Id, which occurs in a turn-on operation, is always sufficiently suppressed within the variation range of the load current Iload. In the present embodiment, β is set to a value within a range greater than zero and less than one. For example, B is set to approximately 0.9.

The first comparator 36 detects a first timing (ta) by comparing the voltage Vi corresponding to the drain current Id and the above-described first reference voltage Ref1. Specifically, when the voltage Vi is higher than the first reference voltage Ref1, a logic output of the first comparator 36 is “Hi”. On the other hand, when the voltage Vi is lower than the first reference voltage Ref1, the logic output of the first comparator 36 is “Lo”. However, the relationship between “Hi” and “Lo” may be reversed, and the logic output of the first comparator 36 only needs to invert at a timing (first timing (ta)) at which the voltage Vi corresponding to the drain current Id of the switching element 11 becomes equal to the first reference voltage Ref1.

Similarly, the second comparator 37 detects a second timing (tb) by comparing the voltage Vi corresponding to the drain current Id and the above-described second reference voltage Ref2. Specifically, when the voltage Vi is higher than the second reference voltage Ref2, a logic output of the second comparator 37 is “Hi”. On the other hand, when the voltage Vi is lower than the second reference voltage Ref2, the logic output of the second comparator 37 is “Lo”. However, the relationship between “Hi” and “Lo” may be reversed, and the logic output of the second comparator 37 only needs to invert at a timing (second timing (tb)) at which the voltage Vi corresponding to the drain current Id of the switching element 11 becomes equal to the second reference voltage Ref2.

Three kinds of current values Ig_on1 to Ig_on3 experimentally determined in advance are stored in the memory 39. The current values Ig_on1 to Ig_on3 take zero or positive values. The current value Ig_on2 is smaller than the current value Ig_on1. The current value Ig_on3 is larger than the current value Ig_on2.

The selection signal output circuit 38 outputs any one of three selection signals SEL1 to SEL3 corresponding to the respective current values Ig_on1 to Ig_on3 to the multiplexer 40 in accordance with timings detected by the first comparator 36 and the second comparator 37. Specifically, the selection signal output circuit 38 outputs the selection signal SEL1 in an initial state at start of a turn-on operation, outputs the selection signal SEL2 when the first timing (ta) is detected by the first comparator 36, and outputs the selection signal SEL3 when the second timing (tb) is detected by the second comparator 37.

The multiplexer 40 selects and outputs any one of the current values Ig_on1 to Ig_on3 stored in the memory 39 in accordance with a selection signal SEL input from the selection signal output circuit 38. Specifically, the multiplexer 40 selects and outputs the current value Ig_on1 when the selection signal SEL1 is input, selects and outputs the current value Ig_on2 when the selection signal SEL2 is input, and selects and outputs the current value Ig_on3 when the selection signal SEL3 is input.

### Operation of Switching Element in Turn-on Operation

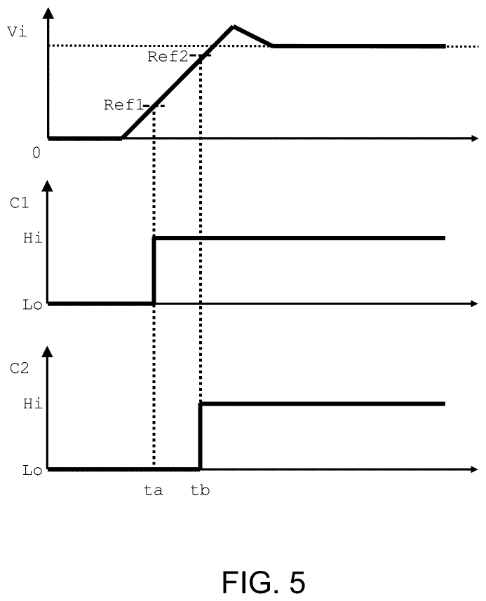

FIGS. 4 and 5 are diagrams for description of an operation of the switching element 11 controlled by the drive circuit 20 according to Embodiment 1 in a turn-on operation.

The uppermost time waveform in FIG. 4 is the time waveform of the control signal IN. The second time waveform in FIG. 4 is the time waveform of the drain current Id of the switching element 11. The third time waveform in FIG. 4 is the time waveform of a voltage Vfc corresponding to a change over time (a time rate of change) of the drain current Id. The fourth time waveform in FIG. 4 is the time waveform of the output voltage Vi of the integrator 31. The fifth time waveform in FIG. 4 is the time waveform of the drive current Ig_on supplied from the drive circuit 20 to the switching element 11. However, the voltage Vfc is illustrated with its sign inverted with respect to the bias voltage Vbias.

The uppermost time waveform in FIG. 5 is the same time waveform of the voltage Vi as that in FIG. 4. The second time waveform in FIG. 5 is the time waveform of a logic output C1 of the first comparator 36. The third time waveform in FIG. 5 is the time waveform of a logic output C2 of the second comparator 37.

At time point t1, when the control signal IN changes from “Lo” to “Hi”, the drive circuit 20 starts supply of the drive current Ig_on including the current value Ig_on1. Specifically, at start of a turn-on operation (t1), the drain current Id of the switching element 11 is zero, and the voltage Vi corresponding to the drain current Id is lower than the first reference voltage Ref1 generated in accordance with the load current Iload at completion of the previous turn-on operation. Accordingly, the logic output C1 of the first comparator 36 at start of a turn-on operation (t1) is “Lo”, and the multiplexer 40 outputs the current value Ig_on1. As a result, the command value output from the turn-on current command circuit 30 is Ig_on1, and the first variable current source 24 outputs a current having the current value Ig_on1. Accordingly, the control signal IN changes from “Lo” to “Hi” at time point t1, and when the first switch 25 is turned on, the drive circuit 20 starts supply of the drive current Ig_on including the current value Ig_on1.

In order to shorten a turn-on delay time (t1 to t2 in FIG. 4) of the switching element 11, it is preferable that the current value Ig_on1 be as large as possible within a range in which operation of the switching element 11 becomes stable. A preferable current value Ig_on1 experimentally determined in advance is stored in the above-described memory 39.

At time point t2, the drain current Id starts to flow, and a drain-source voltage Vds (not illustrated) starts to decrease. At time point ta, the voltage Vi corresponding to the drain current Id becomes equal to the first reference voltage Ref1, and the first timing is detected. Specifically, when the voltage Vi becomes equal to the first reference voltage Ref1, the logic output C1 of the first comparator 36 changes from “Lo” to “Hi”. Consequently, an output of the selection signal output circuit 38 switches from SEL1 to SEL2, and an output of the multiplexer 40 switches from Ig_on1 to Ig_on2. As a result, the command value output from the turn-on current command circuit 30 switches from Ig_on1 to Ig_on2, and the first variable current source 24 outputs a current having the current value Ig_on2. Accordingly, when the first timing is detected at time point ta, the magnitude of the drive current Ig_on supplied from the drive circuit 20 switches from the current value Ig_on1 to the current value Ig_on2.

In order to suppress the surge of the drain current Id, which occurs in a turn-on operation of the switching element 11, it is preferable that the current value Ig_on2 be as small as possible in the range in which operation of the switching element 11 becomes stable. However, when the current value Ig_on2 is excessively small, a turn-on time (t2 to t3 in FIG. 4) of the switching element 11 is long. The current value Ig_on2 is experimentally determined in advance to be a predetermined value smaller than the current value Ig_on1 in consideration of a trade-off therebetween.

At time point tb, the voltage Vi corresponding to the drain current Id becomes equal to the second reference voltage Ref2, and the second timing is detected. Specifically, when the voltage Vi becomes equal to the second reference voltage Ref2, the logic output C2 of the second comparator 37 changes from “Lo” to “Hi”. Consequently, the output of the selection signal output circuit 38 switches from SEL2 to SEL3, and the output of the multiplexer 40 switches from Ig_on2 to Ig_on3. As a result, the command value output from the turn-on current command circuit 30 switches from Ig_on2 to Ig_on3, and the first variable current source 24 outputs a current having the current value Ig_on3. Accordingly, when the second timing is detected at time point tb, the magnitude of the drive current Ig_on supplied from the drive circuit 20 switches from the current value Ig_on2 to the current value Ig_on3.

In order to shorten a turn-on time (t3 to t4 in FIG. 4) of the switching element 11, it is preferable that the current value Ig_on3 be as large as possible within the range in which operation of the switching element 11 becomes stable. A preferable current value Ig_on3 experimentally determined in advance is stored in the above-described memory 39. Note that the current value Ig_on3 may be equal to the current value Ig_on1.

At time point t3, the surge of the drain current Id reaches a maximum value. At this time, in a period from the first timing (ta) to the second timing (tb) before time point t3, since the magnitude of the drive current Ig_on is switched from the current value Ig_on1 to the current value Ig_on2, the maximum value of current surge is significantly suppressed as compared to a case where the magnitude of the drive current Ig_on remains at the current value Ig_on1.

At time point t3 or later, the command value output from the turn-on current command circuit 30 remains at Ig_on3, but the magnitude of the actual drive current Ig_on supplied from the drive circuit 20 to the switching element 11 decreases as electric charge is accumulated at the gate of the switching element 11, and eventually becomes zero.

At time point t4, ringing of the drain current Id converges and the drain current Id becomes equal to the load current Iload, and a conduction state is established between the drain and the source. This completes turn-on of the switching element 11.

At time point ts, the above-described predetermined time T1 elapses, and the pulse generator 32 outputs a sampling pulse. Consequently, the sample-and-hold circuit 33 samples the voltage Vi corresponding to the load current Iload. The first amplifier 34 and the second amplifier 35 generate the first reference voltage Ref1 and the second reference voltage Ref2, respectively, based on the hold voltage Vsmp of the sample-and-hold circuit 33. The first reference voltage Ref1 and the second reference voltage Ref2 generated at this time are generated in accordance with the current actual load current Iload, and are appropriate values in accordance with variation of the load current Iload. The first reference voltage Ref1 and the second reference voltage Ref2 generated at completion of the n-th turn-on operation are used for detection of the first timing (ta) and the second timing (tb), respectively, in the next (n+1)-th turn-on operation.

As described above, time point ts is defined as a timing at which the predetermined time T1 has elapsed after the timing (t1) at which the control signal IN changes from “Lo” to “Hi”, but time point ts only needs to be a time point at which the voltage Vi corresponding to the load current Iload can be stably sampled. The sample-and-hold circuit 33 may sample the voltage Vi corresponding to the load current Iload once a plurality of times or at a predetermined period, instead of sampling the voltage Vi corresponding to the load current Iload at completion of each turn-on operation. Including this case, in the present embodiment, the first reference voltage Ref1 and the second reference voltage Ref2 generated at completion of a turn-on operation in the n-th switching cycle are used for detection of the first timing (ta) and the second timing (t2), respectively, in a turn-on operation in the next (n+1)-th switching cycle or later.

As described above, the drive current Ig_on in a turn-on operation of the switching element 11 is controlled so as to suppress the surge of the drain current Id without being affected by variation of the load current Iload.

As described above, the drive circuit 20 according to Embodiment 1 includes the integrator 31 that outputs the integrated value Vi of the voltage Vfc corresponding to a change over time (a time rate of change) of the output current Id of the switching element 11. The drive circuit 20 generates the first reference voltage Ref1 and the second reference voltage Ref2 in accordance with the integrated value Vi, and detects the first timing (ta) and the second timing (t2) based on comparison of the integrated value Vi with the first reference voltage Ref1 and the second reference voltage Ref2.

At start of a turn-on operation of the switching element 11 (t1), the drive circuit 20 sets a command value for the current supply circuit to the current value Ig_on1. When the first timing (ta) is detected during a turn-on transition period (t1 to t4) of the switching element 11, the drive circuit 20 switches the command value for the current supply circuit to the current value Ig_on2 smaller than the current value Ig_on1. When the second timing (tb) is detected during the turn-on transition period of the switching element 11, the drive circuit 20 switches the command value for the current supply circuit to the current value Ig_on3 larger than the current value Ig_on2.

With the above-described characteristics, the drive circuit 20 according to Embodiment 1 can effectively suppress current surge that occurs in a turn-on operation of the switching element 11. Moreover, in general, an integrator is robust against noise. Accordingly, the drive circuit according to Embodiment 1 can detect the first timing (ta) and the second timing (tb) at high accuracy without being affected by noise, and can switch the command value for the current supply circuit at accurate timings.

The drive circuit 20 also generates the first reference voltage Ref1 and the second reference voltage Ref2 in accordance with the load current Iload after completion of a turn-on operation of the switching element 11. Accordingly, current surge that occurs in a turn-on operation of the switching element 11 can be suppressed without being affected by variation of the load current Iload.

### Embodiment 2

In Embodiment 1 described above, the first timing (ta) and the second timing (tb) can be detected only in a period in which the drain current Id is smaller than the load current Iload. This is because, in a period in which the drain current Id exceeds the load current Iload, whether the reference voltages are exceeded cannot be determined based only on the output values of the comparators. However, in Embodiment 2, the first timing (ta) and the second timing (tb) can be detected even in a period in which the drain current Id is larger than the load current Iload.

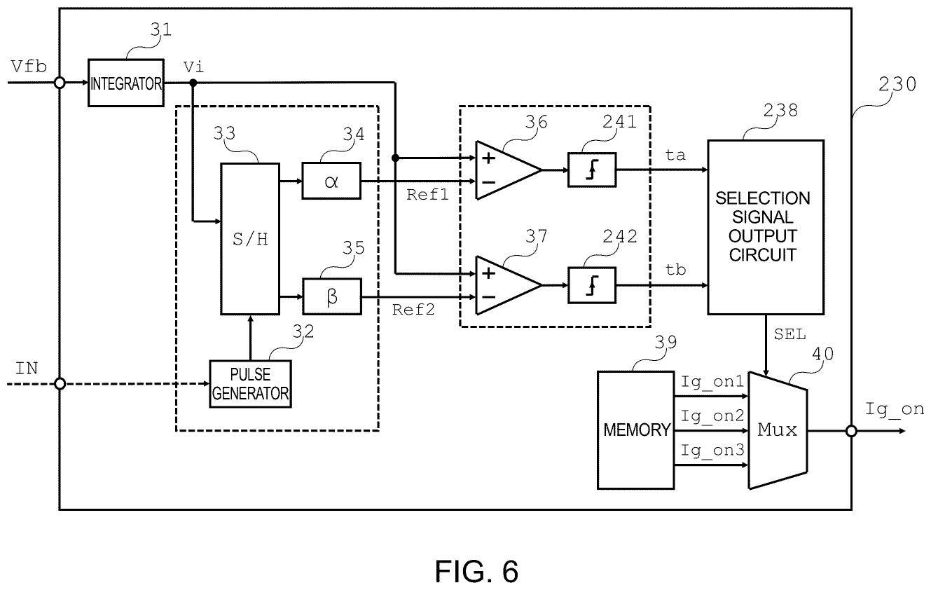

FIG. 6 is a diagram illustrating a detailed configuration of a turn-on current command circuit 230 according to Embodiment 2. The turn-on current command circuit 230 includes a first edge detector 241 provided at a subsequent stage of the first comparator 36, and a second edge detector 242 provided at a subsequent stage of the second comparator 37, in addition to the configuration of Embodiment 1. In the present embodiment, the amplification factor α of the first amplifier 34 and the amplification factor β of the second amplifier 35 may each be a value greater than one. For example, a is set to approximately 0.3, and β is set to approximately 1.2.

The first edge detector 241 detects a rising edge of the logic output of the first comparator 36. Specifically, when the logic output of the first comparator 36 rises from “Lo” to “Hi”, the first edge detector 241 outputs a pulse. On the other hand, when the logic output of the first comparator 36 falls from “Hi” to “Lo”, the first edge detector 241 does not output a pulse. The first comparator 36 and a first edge detector 241 constitute a first timing detection circuit of the turn-on current command circuit 230.

Similarly, the second edge detector 242 detects a rising edge of the logic output of the second comparator 37. Specifically, when the logic output of the second comparator 37 rises from “Lo” to “Hi”, the second edge detector 242 outputs a pulse. On the other hand, when the logic output of the second comparator 37 falls from “Hi” to “Lo”, the second edge detector 242 does not output a pulse. The second comparator 37 and the second edge detector 242 constitute the second timing detection circuit of the turn-on current command circuit 230.

A selection signal output circuit 238 outputs the selection signal SEL1 in an initial state at start of a turn-on operation, outputs the selection signal SEL2 when the first timing (ta) is detected by the first edge detector 241, and outputs the selection signal SEL3 when the second timing (tb) is detected by the second edge detector 242.

### Operation of Switching Element in Turn-on Operation

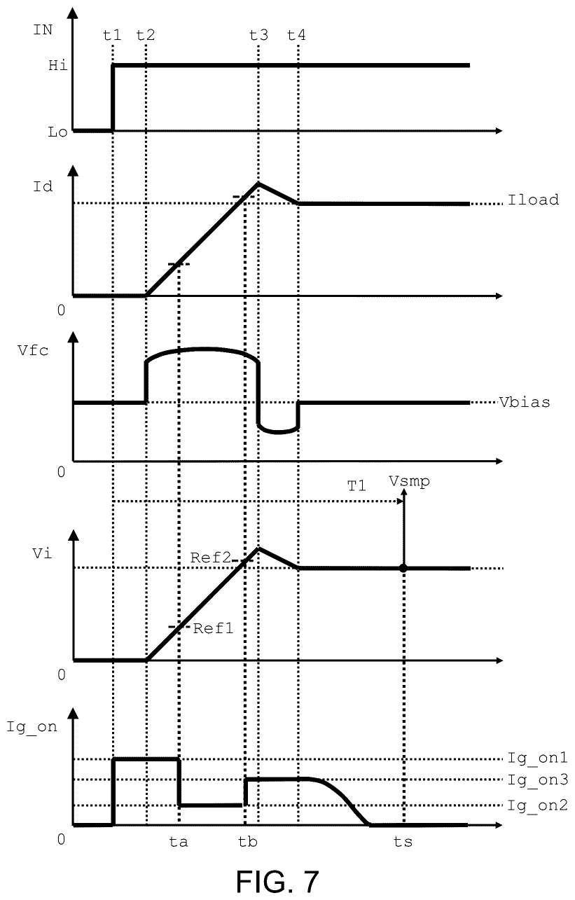

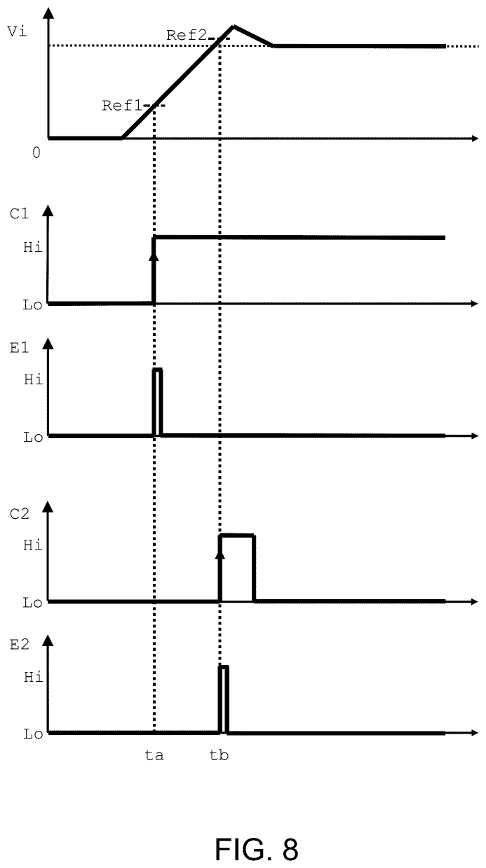

FIGS. 7 and 8 are diagrams for description of an operation of the switching element 11 controlled by a drive circuit according to Embodiment 2 in a turn-on operation.

The uppermost time waveform in FIG. 7 is the time waveform of the control signal IN. The second time waveform in FIG. 7 is the time waveform of the drain current Id of the switching element 11. The third time waveform in FIG. 7 is the time waveform of the voltage Vfc corresponding to a change over time (a time rate of change) of the drain current Id. The fourth time waveform in FIG. 7 is the time waveform of the output voltage Vi of the integrator 31. The fifth time waveform in FIG. 7 is the time waveform of the drive current Ig_on supplied from the drive circuit to the switching element 11. However, the voltage Vfc is illustrated with its sign inverted with respect to the bias voltage Vbias.

The uppermost time waveform in FIG. 8 is the same time waveform of the voltage Vi as that in FIG. 7. The second time waveform in FIG. 8 is the time waveform of the logic output C1 of the first comparator 36. The third time waveform in FIG. 8 is the time waveform of an output E1 of the first edge detector 241. The fourth time waveform in FIG. 8 is the time waveform of the logic output C2 of the second comparator 37. The fifth time waveform in FIG. 8 is the time waveform of an output E2 of the second edge detector 242.

At time point t1, when the control signal IN changes from “Lo” to “Hi”, the drive circuit 20 starts supply of a drive current Ig_on having the current value Ig_on1. At time point t2, the drain current Id starts to flow, and the drain-source voltage Vds (not illustrated) starts to decrease.

At time point ta, the voltage Vi corresponding to the drain current Id becomes equal to the first reference voltage Ref1, and the first timing is detected. Specifically, when the voltage Vi becomes equal to the first reference voltage Ref1, the logic output C1 of the first comparator 36 changes from “Lo” to “Hi”, and the first edge detector 241 detects a rising edge of the logic output C1 and outputs a pulse. Consequently, the output of the selection signal output circuit 238 switches from SEL1 to SEL2, and the output of the multiplexer 40 switches from Ig_on1 to Ig_on2.

At time point tb, the voltage Vi corresponding to the drain current Id becomes equal to the second reference voltage Ref2, and the second timing is detected. Specifically, when the voltage Vi becomes equal to the second reference voltage Ref2, the logic output C2 of the second comparator 37 changes from “Lo” to “Hi”, and the second edge detector 242 detects a rising edge of the logic output C2 and outputs a pulse. Consequently, the output of the selection signal output circuit 238 switches from SEL2 to SEL3, and the output of the multiplexer 40 switches from Ig_on2 to Ig_on3.

At time point t3, the surge of the drain current Id reaches a maximum value. After time point t3, the voltage Vi corresponding to the drain current Id becomes equal to the second reference voltage Ref2 again, but this is not detected as the second timing. This is because, when the voltage Vi becomes equal to the second reference voltage Ref2 again, the logic output C2 of the second comparator 37 changes from “Hi” to “Lo”, but its falling edge is not detected by the second edge detector 242 (refer to C2 and E2 in FIG. 8).

At time point t4, ringing of the drain current Id converges and the drain current Id becomes equal to the load current Iload, which completes turn-on of the switching element 11. At time point ts, the voltage Vi corresponding to the load current Iload is sampled and becomes the hold voltage Vsmp.

As described above, the drive circuit according to Embodiment 2 includes the first edge detector 241 that detects a rising edge of the logic output of the first comparator 36, and the second edge detector 242 that detects a rising edge of the logic output of the second comparator 37. Accordingly, the first timing (ta) and the second timing (tb) can be detected even in a period in which the drain current Id is larger than the load current Iload.

### Embodiment 3

In Embodiment 3, as in Embodiment 2 described above, the first timing (ta) and the second timing (tb) can be detected even in a period in which the drain current Id is larger than the load current Iload. However, in Embodiment 3, the second timing (tb) is detected after the surge of the drain current Id reaches a maximum value.

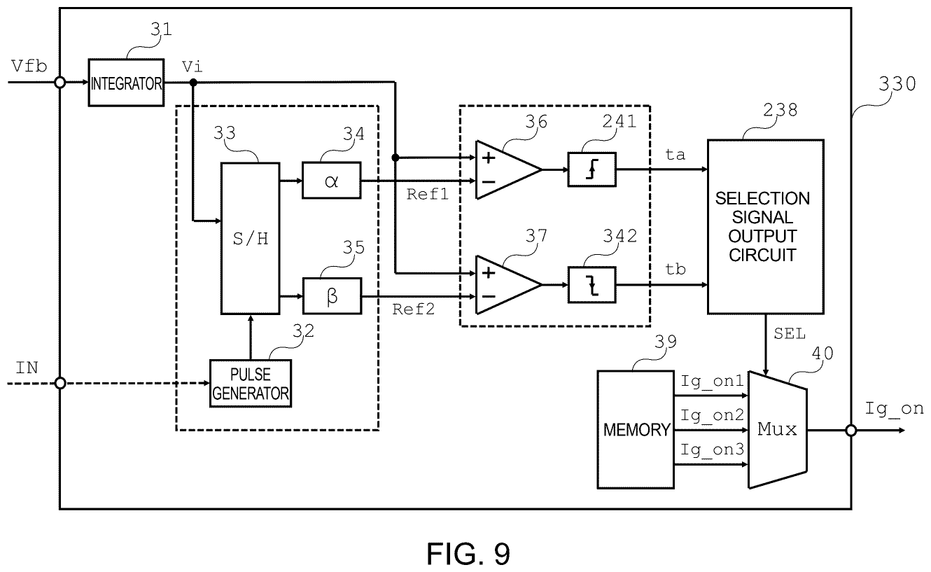

FIG. 9 is a diagram illustrating a detailed configuration of a turn-on current command circuit 330 according to Embodiment 3. A difference from Embodiment 2 is that a second edge detector 342 detects a falling edge of the logic output of the second comparator 37, not a rising edge thereof. For example, the amplification factor α of the first amplifier 34 is set to approximately 0.9. For example, the amplification factor β of the second amplifier 35 is set to approximately 1.2.

### Operation of Switching Element in Turn-on Operation

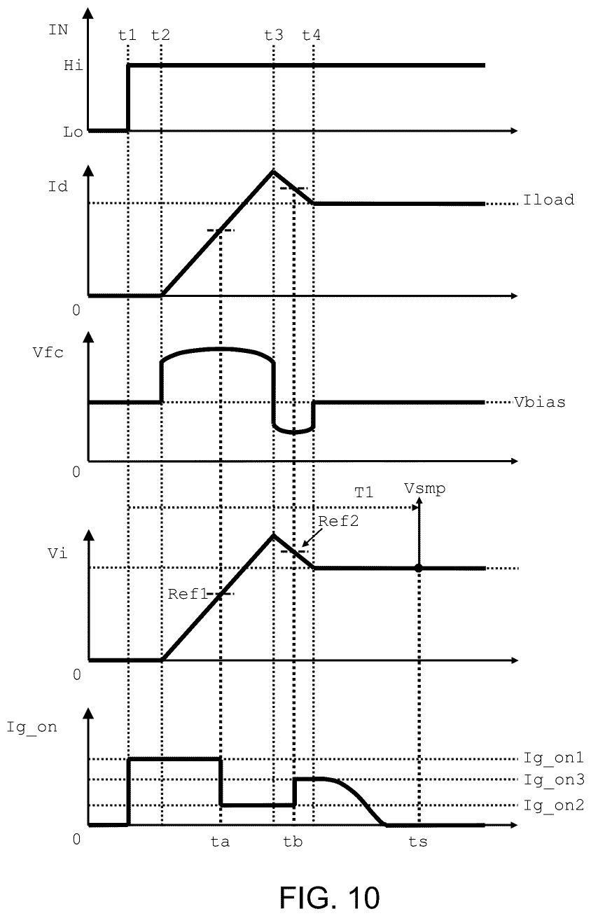

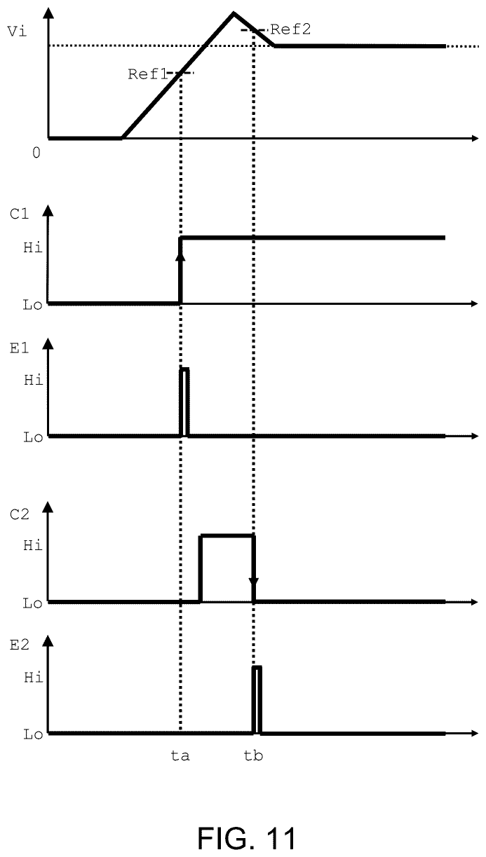

FIGS. 10 and 11 are diagrams for description of an operation of the switching element 11 controlled by a drive circuit according to Embodiment 3 in a turn-on operation.

At time point t1, when the control signal IN changes from “Lo” to “Hi”, the drive circuit starts supply of the drive current Ig_on including the current value Ig_on1. At time point t2, the drain current Id starts to flow, and the drain-source voltage Vds (not illustrated) starts to decrease.

At time point ta, the voltage Vi corresponding to the drain current Id becomes equal to the first reference voltage Ref1, and the first timing is detected. Specifically, when the voltage Vi becomes equal to the first reference voltage Ref1, the logic output C1 of the first comparator 36 changes from “Lo” to “Hi”, and the first edge detector 241 detects a rising edge of the logic output C1 and outputs a pulse. Consequently, the output of the selection signal output circuit 238 switches from SEL1 to SEL2, and the output of the multiplexer 40 switches from Ig_on1 to Ig_on2.

Before time point t3 at which the surge of the drain current Id reaches a maximum value, the voltage Vi corresponding to the drain current Id becomes equal to the second reference voltage Ref2, but this is not detected as the second timing. This is because, when the voltage Vi first becomes equal to the second reference voltage Ref2, the logic output C2 of the second comparator 37 changes from “Lo” to “Hi”, but its rising edge is not detected by the second edge detector 342 (refer to C2 and E2 in FIG. 11).

At time point t3, the surge of the drain current Id reaches a maximum value. At time point tb later than time point t3, the voltage Vi corresponding to the drain current Id becomes equal to the second reference voltage Ref2 again, and the second timing is detected. Specifically, when the voltage Vi becomes equal to the second reference voltage Ref2 again, the logic output C2 of the second comparator 37 changes from “Hi” to “Lo”, and the second edge detector 242 detects a falling edge of the logic output C2 and outputs a pulse. Consequently, the output of the selection signal output circuit 238 switches from SEL2 to SEL3, and the output of the multiplexer 40 switches from Ig_on2 to Ig_on3.

At time point t4, ringing of the drain current Id converges and the drain current Id becomes equal to the load current Iload, which completes turn-on of the switching element 11. At time point ts, the voltage Vi corresponding to the load current Iload is sampled and becomes the hold voltage Vsmp.

As described above, the drive circuit according to Embodiment 3 can detect the second timing (tb) after the surge of the drain current Id reaches a maximum value.

### Embodiment 4

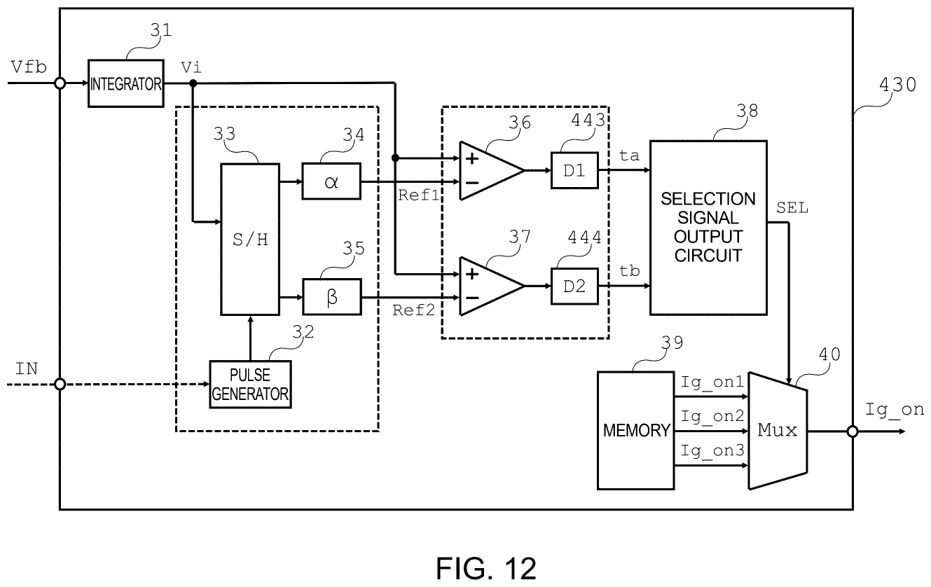

FIG. 12 is a diagram illustrating a detailed configuration of a turn-on current command circuit 430 according to Embodiment 4. In the turn-on current command circuit 430, a first delay circuit 443 and a second delay circuit 444 are respectively provided at subsequent stages of the first comparator 36 and the second comparator 37 of Embodiment 1.

A rewritable memory such as a flash memory is included inside each of the first delay circuit 443 and the second delay circuit 444. The first delay circuit 443 outputs the logic output of the first comparator 36 after delaying the logic output by a first delay time that is set in the memory. The second delay circuit 444 outputs the logic output of the second comparator 37 after delaying the logic output by a second delay time that is set in the memory. A user of the drive circuit can adjust the first timing (ta) and the second timing (tb) by setting the delay times of the first delay circuit 443 and the second delay circuit 444 to desired values.

### Embodiment 5

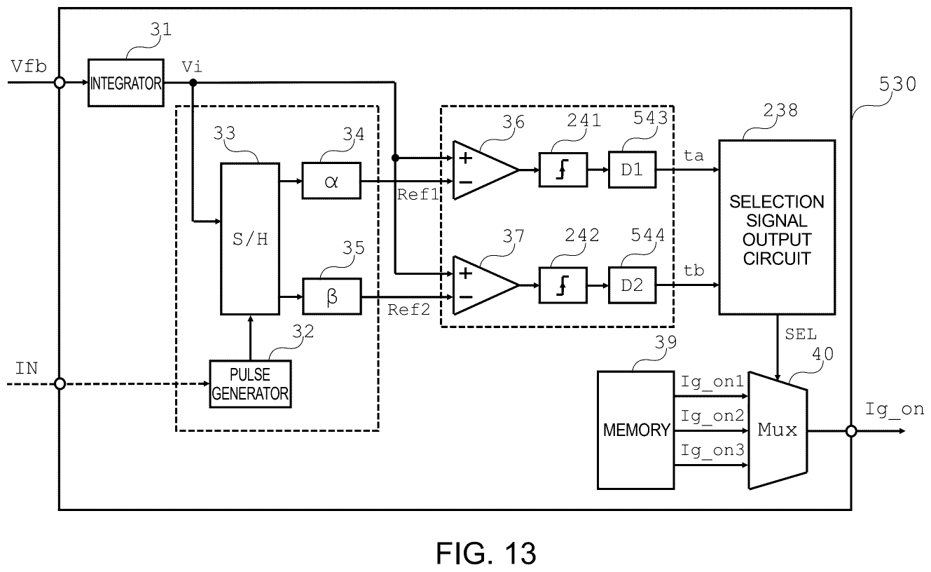

FIG. 13 is a diagram illustrating a detailed configuration of a turn-on current command circuit 530 according to Embodiment 5. In the turn-on current command circuit 530, a first delay circuit 543 and a second delay circuit 544 are respectively provided at subsequent stages of the first edge detector 241 and the second edge detector 242 of Embodiment 2. As in Embodiment 4 described above, the user of the drive circuit can adjust the first timing (ta) and the second timing (tb) by setting the delay times of the first delay circuit 543 and the second delay circuit 544 to desired values.

### Embodiment 6

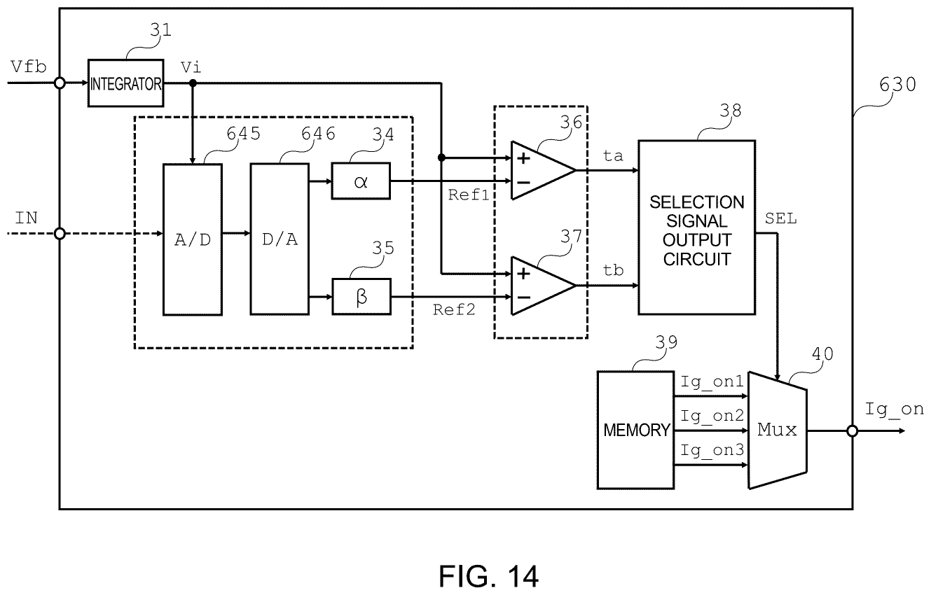

FIG. 14 is a diagram illustrating a detailed configuration of a turn-on current command circuit 630 according to Embodiment 6. In the turn-on current command circuit 630, an A/D converter 645 and a D/A converter 646 are provided in place of the pulse generator 32 and the sample-and-hold circuit 33 of Embodiment 1. The components 645 and 646 and the components 34 and 35 constitute a reference value generator of the turn-on current command circuit 630.

At a timing at which the predetermined time T1 has elapsed after the control signal IN changes from “Lo” to “Hi”, the A/D converter 645 converts the analog voltage Vi into a digital value and holds the digital value. The D/A converter 646 converts the digital value held by the A/D converter 645 into an analog voltage, and outputs the analog voltage. Accordingly, a voltage corresponding to the load current Iload after completion of a turn-on operation of the switching element 11 is output from the A/D converter 645. With this configuration as well, the same function as that of the reference value generator of Embodiment 1 can be achieved.

### Embodiment 7

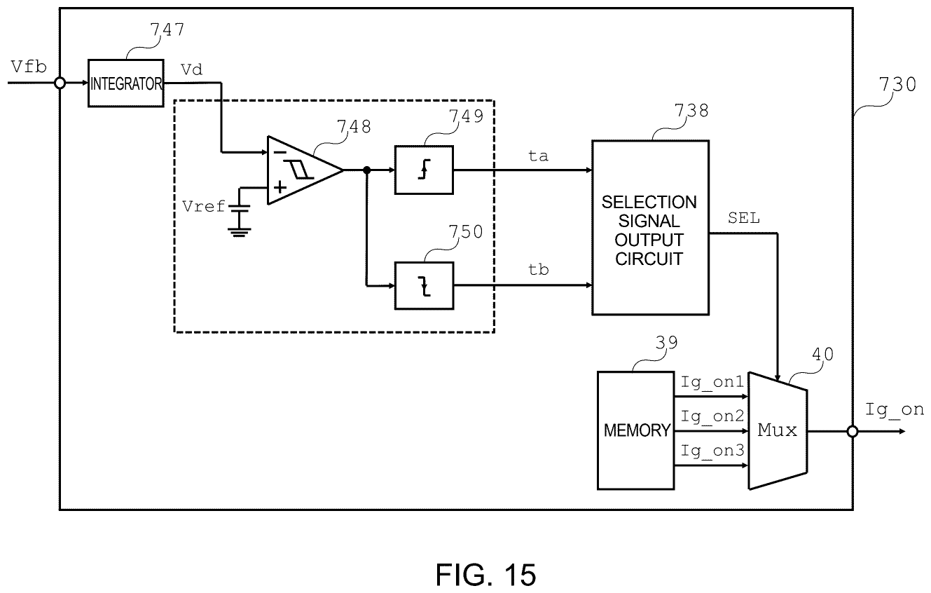

FIG. 15 is a diagram illustrating a detailed configuration of a turn-on current command circuit 730 according to Embodiment 7. The turn-on current command circuit 730 includes a differentiator (arithmetic circuit) 747 in place of the integrator 31 of Embodiment 1. The turn-on current command circuit 730 also includes a hysteresis comparator 748, a third edge detector 749, and a fourth edge detector 750. The components 748 to 750 constitute a timing detection circuit of the turn-on current command circuit 730. Note that no constituent components corresponding to the reference value generator in Embodiments 1 to 6 described above are present in the turn-on current command circuit 730.

The differentiator 747 outputs a voltage Vd obtained by differentiating the voltage Vfb. Since the voltage Vfb is a physical quantity corresponding to a change over time (a time rate of change) of the output current Id of the switching element 11, the output voltage Vd of the differentiator 747 is a physical quantity corresponding to the second derivative of the output current Id of the switching element 11.

The hysteresis comparator 748 operates in accordance with the result of comparison between the voltage Vd applied to its inverting input with a third reference voltage Ref3 and a fourth reference voltage Ref4 that are determined in accordance with a reference voltage Vref applied to its non-inverting input. Specifically, a logic output of the hysteresis comparator 748 changes from “Lo” to “Hi” at a timing at which the voltage Vd falls below the third reference voltage Ref3, and changes from “Hi” to “Lo” at a timing at which the voltage Vd exceeds the fourth reference voltage Ref4.

The third edge detector 749 detects the first timing (ta) by detecting a rising edge of the logic output of the hysteresis comparator 748. The fourth edge detector 750 detects the second timing (tb) by detecting a falling edge of the logic output of the hysteresis comparator 748.

### Operation of Switching Element in Turn-on Operation

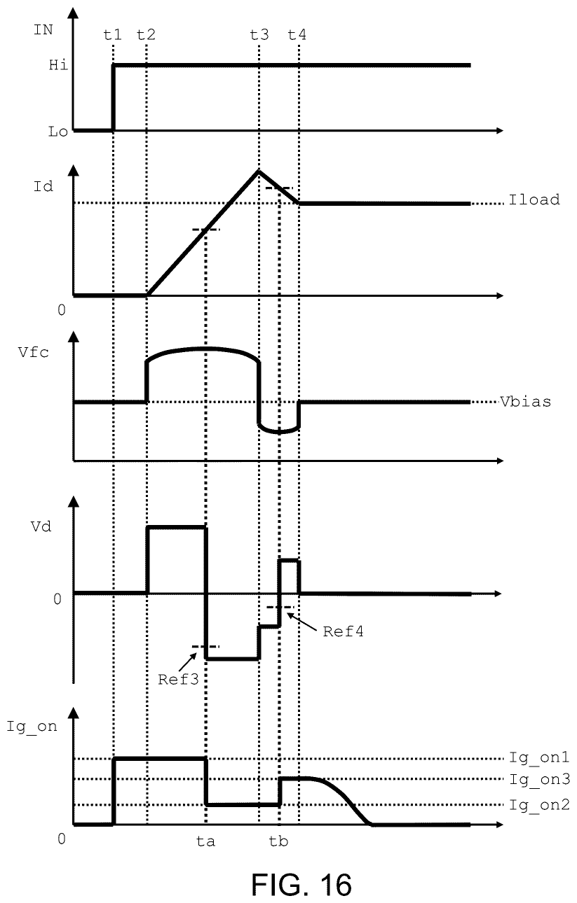

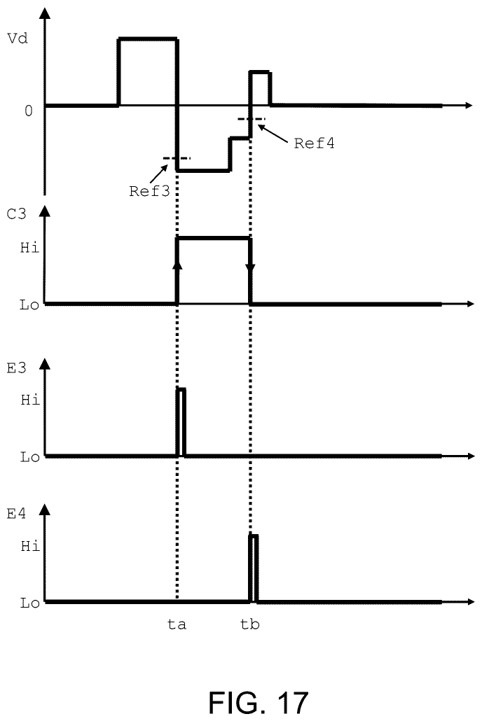

FIGS. 16 and 17 are diagrams for description of an operation of the switching element 11 controlled by a drive circuit according to Embodiment 7 in a turn-on operation.

The uppermost time waveform in FIG. 16 is the time waveform of the control signal IN. The second time waveform in FIG. 16 is the time waveform of the drain current Id of the switching element 11. The third time waveform in FIG. 16 is the time waveform of the voltage Vfc corresponding to a change over time (a time rate of change) of the drain current Id. The fourth time waveform in FIG. 16 is the time waveform of the output voltage Vd of the differentiator 747. The fifth time waveform in FIG. 16 is the time waveform of the drive current Ig_on supplied from the drive circuit to the switching element 11. However, the voltage Vfc is illustrated with its sign inverted with respect to the bias voltage Vbias.

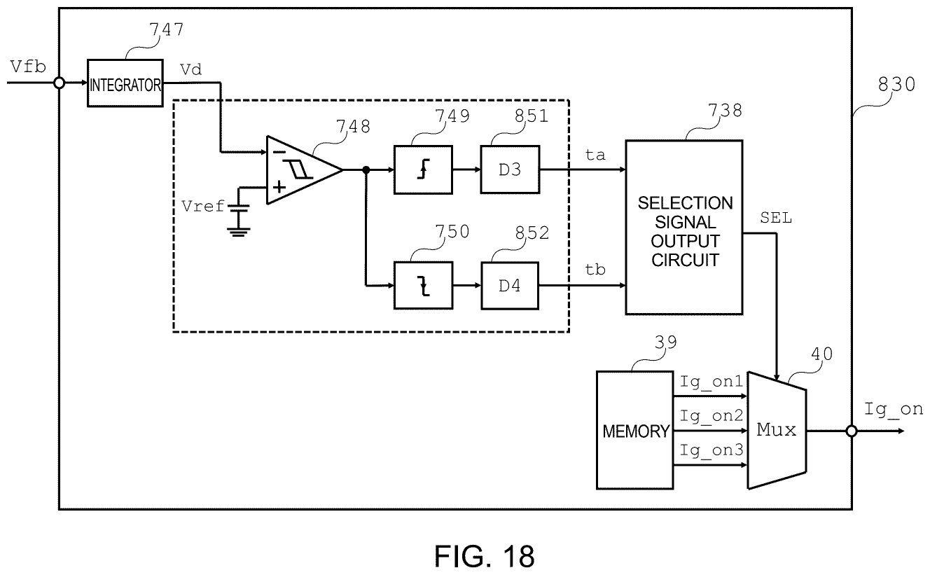

The uppermost time waveform in FIG. 17 is the same time waveform of the voltage Vd as that in FIG. 16. The second time waveform in FIG. 17 is the time waveform of a logic output C3 of the hysteresis comparator 748. The third time waveform in FIG. 18 is the time waveform of an output E3 of the third edge detector 749. The fourth time waveform in FIG. 17 is the time waveform of an output E4 of the fourth edge detector 750.

At time point t1, when the control signal IN changes from “Lo” to “Hi”, the drive circuit starts supply of the drive current Ig_on including the current value Ig_on1. At time point t2, the drain current Id starts to flow, and the drain-source voltage Vds (not illustrated) starts to decrease.

At time point ta, the first timing is detected by the third edge detector 749 detecting a rising edge of the logic output C3 of the hysteresis comparator 748. Specifically, a timing at which the logic output C3 of the hysteresis comparator 748 changes from “Hi” to “Lo” corresponds to a local maximum value in the graph of the voltage Vd in FIG. 16, and is always included in a period (t1 to t3 in FIG. 16) from a time at which the drain current Id becomes zero to a time at which the drain current Id reaches the surge maximum value. The third edge detector 749 detects this timing as the first timing (ta). When a pulse is output from the third edge detector 749, an output of a selection signal output circuit 738 switches from SEL1 to SEL2, and the output of the multiplexer 40 switches from Ig_on1 to Ig_on2.

At time point t3, the surge of the drain current Id reaches a maximum value. At time point tb later than time point t3, the second timing is detected by the fourth edge detector 750 detecting a falling edge of the logic output C3 of the hysteresis comparator 748. Specifically, a timing at which the logic output C3 of the hysteresis comparator 748 changes from “Hi” to “Lo” corresponds to a local minimum value in the graph of the voltage Vd in FIG. 16, and is always included in a period (t3 to t4 in FIG. 16) from a time at which the drain current Id reaches the surge maximum value to a time at which the drain current Id converges to the load current Iload. The fourth edge detector 750 detects this timing as the second timing (tb). When a pulse is output from the fourth edge detector 750, the output of the selection signal output circuit 738 switches from SEL2 to SEL3, and the output of the multiplexer 40 switches from Ig_on2 to Ig_on3. At time point t4, ringing of the drain current Id converges and becomes equal to the load current Iload, which completes turn-on of the switching element 11.

As described above, the drive circuit according to Embodiment 7 does not need to sample a voltage corresponding to the load current Iload at completion of a turn-on operation, and also does not need to generate the third reference voltage Ref3 and the fourth reference voltage Ref4 every time in accordance with the load current Iload. Nevertheless, the drive circuit according to Embodiment 7 can perform control of a current value in accordance with the current state of the drain current Id of the switching element 11 by using the voltage Vd corresponding to the second derivative of the drain current Id.

### Embodiment 8

FIG. 18 is a diagram illustrating a detailed configuration of a turn-on current command circuit 830 according to Embodiment 8. In the turn-on current command circuit 830, a third delay circuit 851 and a fourth delay circuit 852 are respectively provided at subsequent stages of the third edge detector 749 and the fourth edge detector 750 of Embodiment 7.

A rewritable memory such as a flash memory is included inside each of the third delay circuit 851 and the fourth delay circuit 852. The third delay circuit 851 outputs a logic output of the third edge detector 749 after delaying the logic output by a third delay time that is set in the memory. The fourth delay circuit 852 outputs a logic output of the fourth edge detector 750 after delaying the logic output by a fourth delay time that is set in the memory. The user of the drive circuit can adjust the first timing (ta) and the second timing (tb) by setting the delay times of the third delay circuit 851 and the fourth delay circuit 852 to desired values.

### Embodiment 9

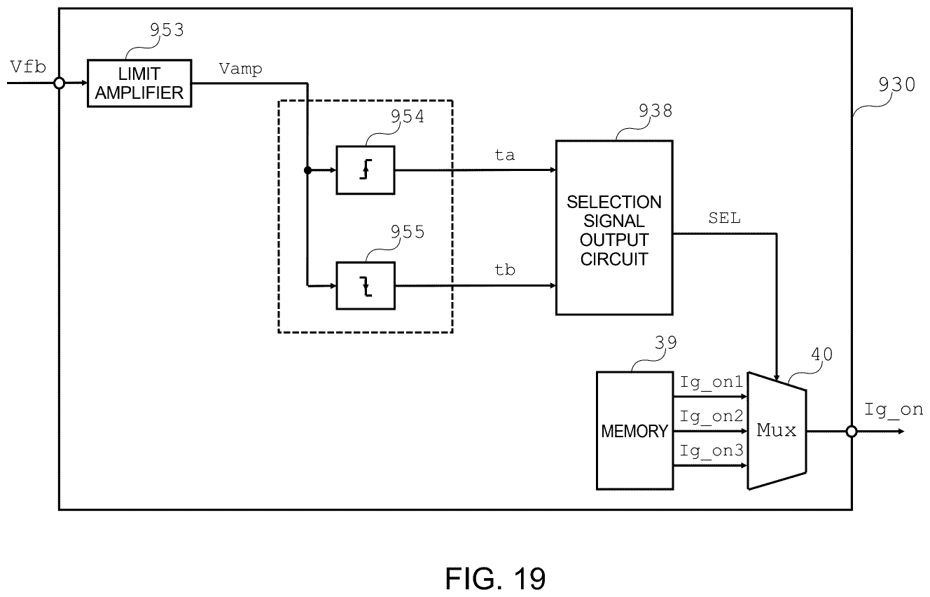

FIG. 19 is a diagram illustrating a detailed configuration of a turn-on current command circuit 930 according to Embodiment 9. The turn-on current command circuit 930 includes a limit amplifier (arithmetic circuit) 953 in place of the integrator 31 of Embodiment 1. The turn-on current command circuit 930 also includes a fifth edge detector 954 and a sixth edge detector 955. The components 954 and 955 constitute a timing detection circuit of the turn-on current command circuit 930. Note that no constituent components corresponding to the reference value generator in Embodiments 1 to 6 described above are present in the turn-on current command circuit 930.

The limit amplifier 953 amplifies the voltage Vfb and outputs an amplification result while limiting the amplification result within a predetermined voltage range. In the present embodiment, the predetermined voltage range is set to a range from 0 V, which corresponds to the logic value “Lo”, to 5 V, which corresponds to the logic value “Hi”. Accordingly, the limit amplifier 953 outputs a voltage Vamp in the range of 0 to 5 V in accordance with the voltage Vfb.

The fifth edge detector 954 detects the first timing (ta) by detecting a rising edge of the output voltage Vamp of the limit amplifier 953. The sixth edge detector 955 detects the second timing (tb) by detecting a falling edge of the output voltage Vamp of the limit amplifier 953.

### Operation of Switching Element in Turn-on Operation

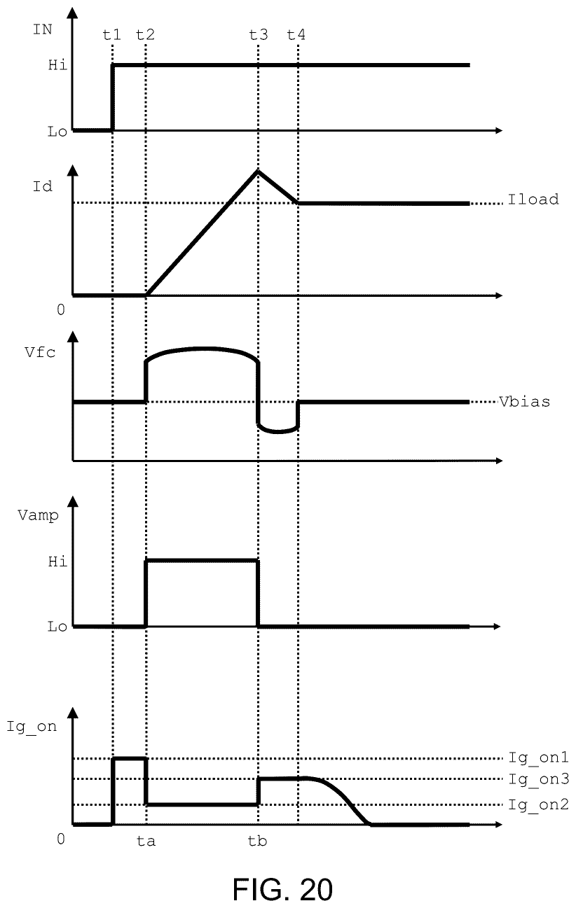

FIG. 20 is a diagram for description of an operation of the switching element 11 controlled by a drive circuit according to Embodiment 9 in a turn-on operation.

The uppermost time waveform in FIG. 20 is the time waveform of the control signal IN. The second time waveform in FIG. 20 is the time waveform of the drain current Id of the switching element 11. The third time waveform in FIG. 20 is the time waveform of the voltage Vfc corresponding to a change over time (a time rate of change) of the drain current Id. The fourth time waveform in FIG. 20 is the time waveform of the output voltage Vamp of the limit amplifier 953. The fifth time waveform in FIG. 20 is the time waveform of the drive current Ig_on supplied from the drive circuit to the switching element 11. However, the voltage Vfc is illustrated with its sign inverted with respect to the bias voltage Vbias.

At time point t1, when the control signal IN changes from “Lo” to “Hi”, the drive circuit starts supply of the drive current Ig_on including the current value Ig_on1. At time point t2, the drain current Id starts to flow, and the drain-source voltage Vds (not illustrated) starts to decrease. At this time, the first timing (ta) is detected by the fifth edge detector 954 detecting a rising edge of the output voltage Vamp of the limit amplifier 953. Consequently, an output of a selection signal output circuit 938 switches from SEL1 to SEL2, and the output of the multiplexer switches from Ig_on1 to Ig_on2.

At time point t3, the surge of the drain current Id reaches a maximum value. At this time, the second timing (tb) is detected by the sixth edge detector 955 detecting a falling edge of the output voltage Vamp of the limit amplifier 953. Consequently, the output of the selection signal output circuit 938 switches from SEL2 to SEL3, and the output of the multiplexer 40 switches from Ig_on2 to Ig_on3. At time point t4, ringing of the drain current Id converges and the drain current Id becomes equal to the load current Iload, which completes turn-on of the switching element 11.

As described above, the drive circuit according to Embodiment 9 can perform control of the current value of the switching element 11 in an extremely simple manner by using the voltage Vamp obtained by amplifying the voltage Vfc corresponding to a change over time (a time rate of change) of the drain current Id with the limit amplifier 953.

### Embodiment 10

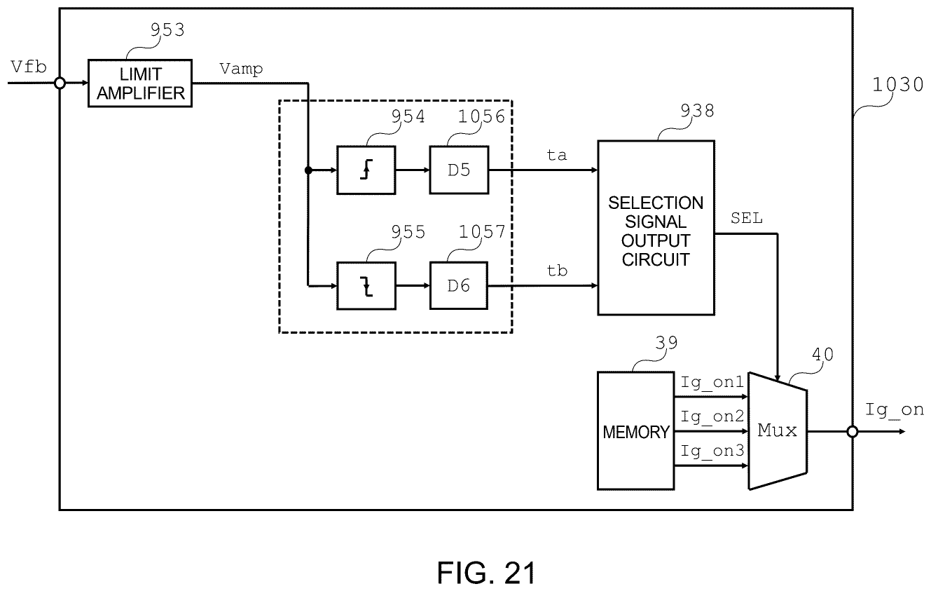

FIG. 21 is a diagram illustrating a detailed configuration of a turn-on current command circuit 1030 according to Embodiment 10. In the turn-on current command circuit 1030, a fifth delay circuit 1056 and a sixth delay circuit 1057 are respectively provided at subsequent stages of the fifth edge detector 954 and the sixth edge detector 955 of Embodiment 9.

A rewritable memory such as a flash memory is included inside each of the fifth delay circuit 1056 and the sixth delay circuit 1057. The fifth delay circuit 1056 outputs a logic output of the fifth edge detector 954 after delaying the logic output by a fifth delay time that is set in the memory. The sixth delay circuit 1057 outputs a logic output of the sixth edge detector 955 after delaying the logic output by a sixth delay time that is set in the memory. The user of the drive circuit can adjust the first timing (ta) and the second timing (tb) by setting the delay times of the fifth delay circuit 1056 and the sixth delay circuit 1057 to desired values.

### Embodiment 11

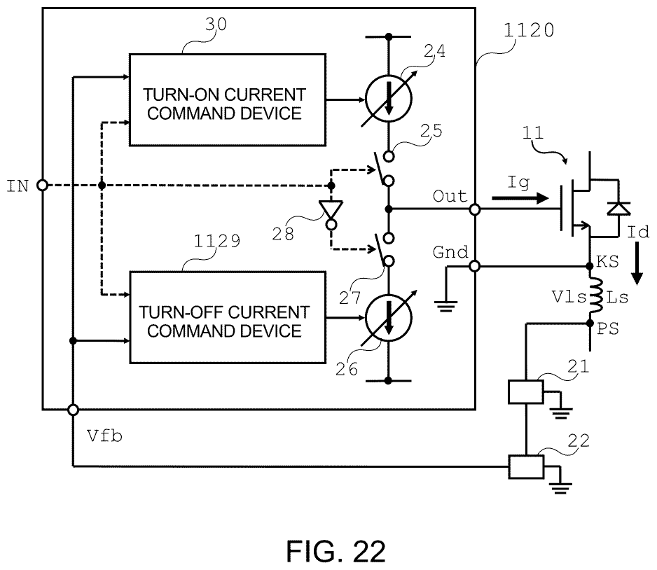

FIG. 22 is a diagram illustrating a detailed configuration of a drive circuit 1120 according to Embodiment 11. The drive circuit 1120 includes a turn-off current command circuit 1129 in place of the turn-off current command circuit 29 in the drive circuit 20 of Embodiment 1. The turn-off current command circuit 1129 controls a command value of the drive current Ig_off to be supplied in a turn-off operation so as to suppress the surge (voltage surge) of the drain-source voltage Vds, which occurs in a turn-off operation of the switching element 11.

### Configuration of Turn-Off Current Command Circuit

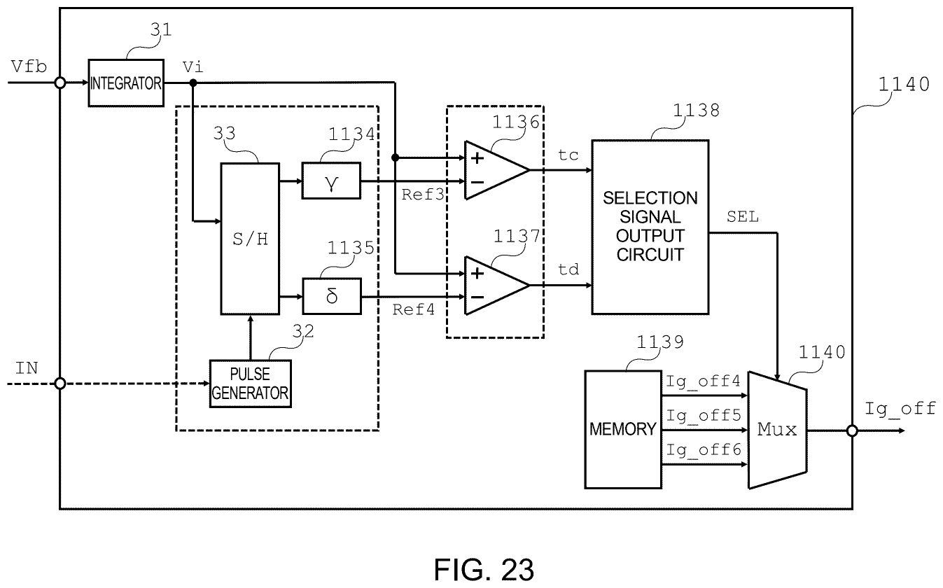

FIG. 23 is a diagram illustrating a detailed configuration of the turn-off current command circuit 1129 according to Embodiment 11. The turn-off current command circuit 1129 includes the integrator (arithmetic circuit) 31, the pulse generator 32, the sample-and-hold circuit 33, a third amplifier 1134, a fourth amplifier 1135, a third comparator 1136, and a fourth comparator 1137. The components 32 to 33 and the components 1134 and 1135 constitute a reference value generator of the turn-off current command circuit 1129. The components 1136 and 1137 constitute a timing detection circuit of the turn-off current command circuit 1129.

The configurations and operations of the integrator 31, the pulse generator 32, and the sample-and-hold circuit 33 are the same as in Embodiment 1.

The third amplifier 1134 amplifies the hold voltage Vsmp of the sample-and-hold circuit 33 by a predetermined amplification factor Y, thereby generating a third reference voltage Ref3 defined by Expression (8) below.

$$\begin{matrix}[ Math . 8 ] & \\ Ref 3 = {γV}_{smp} & ( 8 )\end{matrix}$$

In Expression (8) above, the amplification factor Y is experimentally determined in advance so that the surge of the drain-source voltage Vds, which occurs in a turn-off operation, is always sufficiently suppressed within the variation range of the load current Iload. The amplification factor γ is set to a value within a range greater than zero and less than one. For example, γ is set to approximately 0.9.

Similarly, the fourth amplifier 1135 amplifies the hold voltage Vsmp of the sample-and-hold circuit 33 by a predetermined amplification factor δ, thereby generating a fourth reference voltage Ref4 defined by Expression (9) below.

$$\begin{matrix}[ Math . 9 ] & \\ Ref 4 = {δV}_{smp} & ( 9 )\end{matrix}$$

In Expression (9) above, the amplification factor δ is experimentally determined in advance so that the surge of the drain-source voltage Vds, which occurs in a turn-off operation, is always sufficiently suppressed within the variation range of the load current Iload. The amplification factor γ is set to a value within a range greater than zero and less than one. For example, γ is set to approximately 0.8.

The third comparator 1136 detects the first timing (tc) by comparing the voltage Vi and the third reference voltage Ref3. The fourth comparator 1137 detects the second timing (td) by comparing the voltage Vi and the fourth reference voltage Ref4.

Three kinds of current t values Ig_off4 to Ig_off6 experimentally determined in advance are stored in a memory 1139. The current values Ig_off4 to Ig_off6 take zero or negative values. The absolute value of the current value Ig_off5 is smaller than the absolute value of the current value Ig_off4. The absolute value of the current value Ig_off6 is larger than the absolute value of the current value Ig_off5.

A selection signal output circuit 1138 outputs any one of three selection signals SEL4 to SEL6 corresponding to the respective current values Ig_off4 to Ig_off6 to a multiplexer 1140 in accordance with timings detected by the third comparator 1136 and the fourth comparator 1137.

The multiplexer 1140 selects and outputs any one of the current values Ig_off4 to Ig_off6 stored in the memory 1139 in accordance with the selection signal SEL input from the selection signal output circuit 1138.

### Operation of Switching Element in Turn-Off Operation

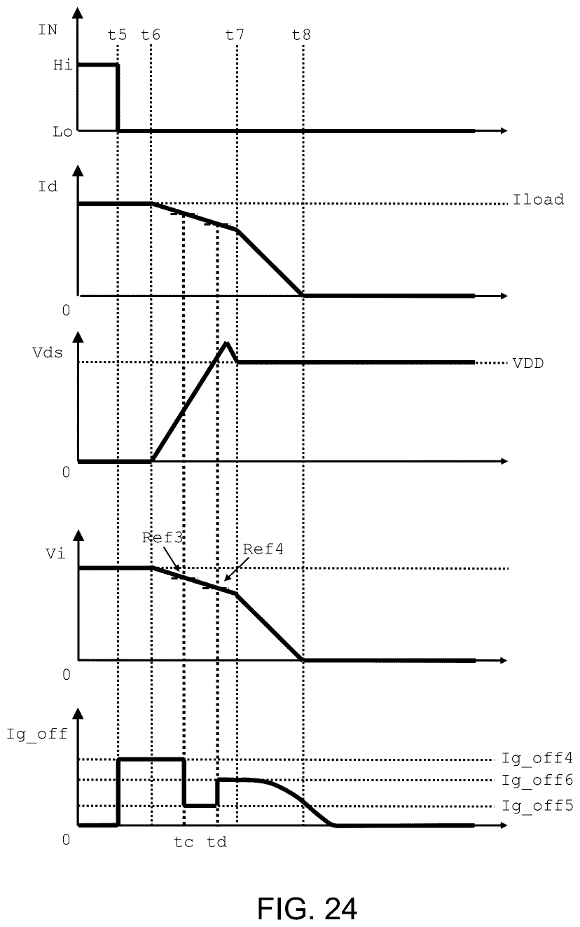

FIG. 24 is a diagram for description of an operation of the switching element 11 controlled by the drive circuit 1120 according to Embodiment 11 in a turn-off operation.

The uppermost time waveform in FIG. 24 is the time waveform of the control signal IN. The second time waveform in FIG. 24 is the time waveform of the drain current Id of the switching element 11. The third time waveform in FIG. 24 is the time waveform of the drain-source voltage Vds of the switching element 11. The fourth time waveform in FIG. 24 is the time waveform of the output voltage Vi of the integrator 31. The fifth time waveform in FIG. 24 is the time waveform of the drive current Ig_off supplied from the drive circuit 20 to the switching element 11. However, the drive current Ig_off is illustrated with its sign inverted.

At time point t5, when the control signal IN changes from “Hi” to “Lo”, the drive circuit 1120 starts supply of the drive current Ig_off having a current value Ig_off1. In order to shorten a turn-off delay time (t5 to t6 in FIG. 24) of the switching element 11, it is preferable that the absolute value of the current value Ig_off4 be as large as possible within the range in which operation of the switching element 11 becomes stable. A preferable current value Ig_off4 experimentally determined in advance is stored in the memory 1139.

At time point t6, the drain current Id starts to decrease, and the drain-source voltage Vds starts to increase. At time point tc during a turn-off transition period (t5 to t8) of the switching element 11, the voltage Vi corresponding to the drain current Id becomes equal to the third reference voltage Ref3, and the first timing is detected. Specifically, when the voltage Vi becomes equal to the third reference voltage Ref3, a logic output of the third comparator 1136 is inverted. Consequently, an output of the selection signal output circuit 1138 switches from SEL1 to SEL2, and an output of the multiplexer 1140 switches from Ig_off4 to Ig_off5. Accordingly, when the first timing is detected at time point tc, the magnitude of the drive current Ig_off supplied from the drive circuit 1120 switches from the current value Ig_off4 to the current value Ig_off5.

In order to suppress the surge of the drain-source voltage Vds, which occurs in a turn-off operation of the switching element 11, it is preferable that the absolute value of the current value Ig_off5 be as small as possible within the range in which operation of the switching element 11 becomes stable. However, when the absolute value of the current value Ig_off5 is excessively small, a turn-off time (t6 to t7 in FIG. 24) of the switching element 11 is long. The absolute value of the current value Ig_off5 is experimentally determined in advance to be a predetermined value smaller than the absolute value of the current value Ig_off4 in consideration of a trade-off therebetween.

At time point td during the turn-off transition period (t5 to t8) of the switching element 11, the voltage Vi corresponding to the drain current Id becomes equal to the fourth reference voltage Ref4, and the second timing is detected. Specifically, when the voltage Vi becomes equal to the fourth reference voltage Ref4, a logic output of the fourth comparator 1137 is inverted. Consequently, the output of the selection signal output circuit 1138 switches from SEL2 to SEL3, and the output of the multiplexer 1140 switches from Ig_off5 to Ig_off6. Accordingly, when the second timing is detected at time point td, the magnitude of the drive current Ig_off supplied from the drive circuit 1120 switches from the current value Ig_off5 to the current value Ig_off6.

In order to shorten a turn-off time (t7 to t8 in FIG. 24) of the switching element 11, it is preferable that the absolute value of the current value Ig_off6 be as large as possible within the range in which operation of the switching element 11 becomes stable. A preferable current value Ig_off6 experimentally determined in advance is stored in the memory 1139. Note that the current value Ig_off6 may be equal to the current value Ig_off4.

At time point t7, ringing of the drain-source voltage Vds converges and the drain-source voltage Vds becomes equal to the power voltage VDD. At this time, in a period from the first timing (tc) to the second timing (td) before time point t7, since the magnitude of the drive current Ig_off is switched from the current value Ig_off4 to the current value Ig_off5, the maximum value of voltage surge is significantly suppressed as compared to a case where the magnitude of the drive current Ig_off remains at the current value Ig_off4.

At time point t7 or later, the command value output from the turn-off current command circuit 1129 remains at Ig_off6, but the magnitude of the actual drive current Ig_off supplied from the drive circuit 1120 to the switching element 11 decreases as electric charge accumulated in the gate of the switching element 11 is removed, and eventually becomes zero.

At time point t8, the drain current Id becomes zero, and a non-conduction state is established between the drain and the source. This completes turn-off of the switching element 11.

Although not illustrated in FIG. 24, “in the next turn-on operation” of the switching element 11, the sample-and-hold circuit 33 samples the voltage Vi corresponding to the load current Iload. The third amplifier 1134 and the fourth amplifier 1135 generate the third reference voltage Ref3 and the fourth reference voltage Ref4, respectively, based on the hold voltage Vsmp of the sample-and-hold circuit 33. The third reference voltage Ref3 and the second reference voltage Ref2 generated at this time are generated in accordance with the current actual load current Iload, and are appropriate values in accordance with variation of the load current Iload. The third reference voltage Ref3 and the fourth reference voltage Ref4 generated at completion of a turn-on operation in the n-th switching cycle are used for detection of the first timing (tc) and the second timing (td), respectively, in a turn-off operation in the next (n+1)-th switching cycle.

The sample-and-hold circuit 33 may sample the voltage Vi corresponding to the load current Iload once a plurality of times or at a predetermined period, instead of sampling the voltage Vi depending on the load current Iload at completion of each turn-on operation. Including this case, in the present embodiment, the third reference voltage Ref3 and the fourth reference voltage Ref4 generated at completion of a turn-on operation in the n-th switching cycle are used for detection of the first timing (tc) and the second timing (td), respectively, in a turn-off operation in the next (n+1)-th switching cycle or later.

As described above, the drive current Ig_off in a turn-off operation of the switching element 11 is controlled so as to suppress the surge of the drain-source voltage Vds without being affected by variation of the load current Iload.

As described above, the drive circuit 1120 according to Embodiment 11 generates the third reference voltage Ref3 and the fourth reference voltage Ref4 in accordance with the integrated value Vi of the voltage Vfc corresponding to a change over time (a time rate of change) of the output current Id of the switching element 11, and detects the first timing (tc) and the second timing (td) based on comparison of the integrated value Vi with the third reference voltage Ref3 and the fourth reference voltage Ref4.

At start of a turn-off operation of the switching element 11 (t5), the drive circuit 1120 sets a command value for the current supply circuit to the current value Ig_off4. When the first timing (tc) is detected during a turn-off period of the switching element 11, the drive circuit 1120 switches the command value for the current supply circuit to the current value Ig_off5 having an absolute value smaller than that of the current value Ig_off4. When the second timing (td) is detected during the turn-off period of the switching element 11, the drive circuit 1120 switches the command value for the current supply circuit to the current value Ig_off6 having an absolute value larger than that of the current value Ig_off5.

With the above-described characteristics, the drive circuit 1120 according to Embodiment 11 can effectively suppress voltage surge that occurs in a turn-off operation of the switching element 11.

### Embodiment 12

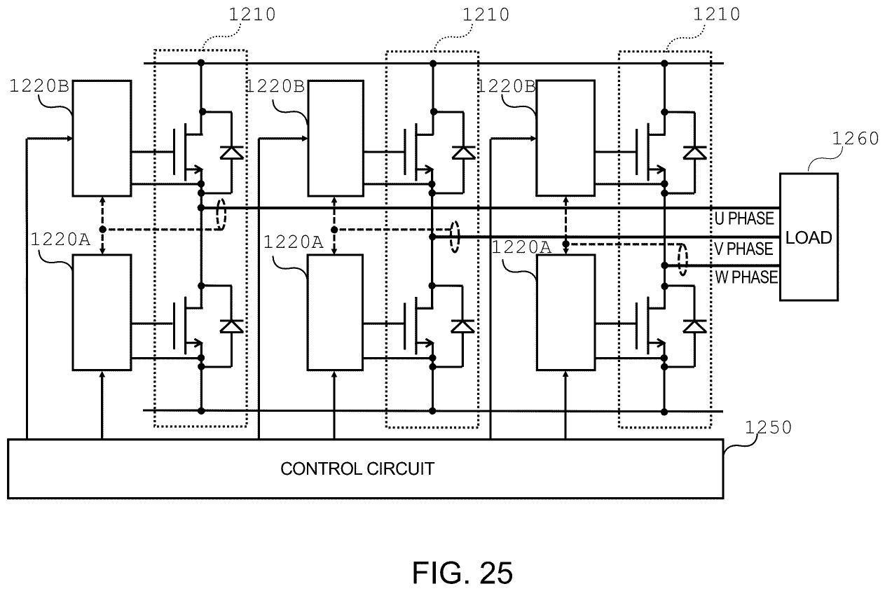

FIG. 25 is a diagram illustrating the configuration of a three-phase inverter that is a power conversion apparatus according to Embodiment 12. The three-phase inverter includes three half-bridge circuits 1210, three low-side drive circuits 1220A, three high-side drive circuits 1220B, and a control circuit 1250. A load 1260 is connected to an output of the three-phase inverter. Each half-bridge circuit 1210 has the same configuration as the half-bridge circuit in Embodiment 1 to 11. Each low-side drive circuit 1220A has the same configuration as the low-side drive circuit in Embodiment 1 to 11. Each high-side drive circuit 1220B has the same configuration as the high-side drive circuit in Embodiment 1 to 11.

The control circuit 1250 supplies a low-side control signal to each low-side drive circuit 1220A, and supplies a high-side control signal to each high-side drive circuit 1220B. The load 1260 is any electronic apparatus or electric apparatus that is driven by three-phase alternating-current power. For example, in a case where the load 1260 is a three-phase alternating-current motor, the control circuit 1250 supplies the PWM-modulated low-side control signal to each low-side drive circuit 1220A, and supplies the PWM-modulated high-side control signal to each high-side drive circuit 1220B.

As another application example, an inverter including a low-side drive circuit, a high-side drive circuit, a half-bridge circuit, and a control circuit may be used as a PV inverter for photovoltaic power generation. In this case, an output of the PV inverter is connected to a power grid.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

The embodiments as described before may be configured as below.

### CLAUSES

Clause 1 (An electronic circuitry) (Embodiment 1). An electronic circuitry comprising:
   an arithmetic circuit configured to perform an operation based on a physical quantity corresponding to a time rate of change of an output current of a switching element controlled in accordance with a control signal instructing turn-on or turn-off;
   a timing detection circuit configured to detect, based on a calculation result of the arithmetic circuit, a first timing and a second timing later than the first timing in a transition period of the turn-on or the turn-off;
   a current supply circuit configured to supply a drive current to the switching element in accordance with a command value of the drive current to be supplied to the switching element; and
   a controller configured to switch a drive current value specified by the command value to a first current value in response to the first timing, and switch the drive current value to a second current value in response to the second timing.
Clause 2 (Embodiment 1). The electronic circuitry according to clause 1, wherein
   the drive current value specified by the command value is a third current value at start of turn-on of the switching element, and
   the controller switches the drive current value specified by the command value to the first current value smaller than the third current value in response to the first timing being detected during a transition period of the turn-on of the switching element.
Clause 3 (Embodiment 1). The electronic circuitry according to clause 2, wherein
   the controller switches the drive current value specified by the command value to the second current value larger than the first current value in response to the second timing being detected during the transition period of the turn-on of the switching element.
Clause 4 (Embodiment 1). The electronic circuitry according to any one of clauses 1 to 3, wherein
   the arithmetic circuit includes an integrator configured to output an integrated value of the physical quantity, and
   the calculation result is the integrated value.
Clause 5 (Embodiment 1). The electronic circuitry according to clause 4, further comprising a reference value generator configured to generate a first reference value and a second reference value in accordance with a steady value of the integrated value after completion of turn-on of the switching element,
   wherein the timing detection circuit detects the first timing based on comparison between the integrated value and the first reference value, and detects the second timing based on comparison between the integrated value and the second reference value.
Clause 6 (Embodiment 1). The electronic circuitry according to clause 5, wherein
   the steady value is an analog signal, and
   the reference value generator includes:
      a pulse generator configured to output a clock pulse in accordance with the control signal;
      a sample-and-hold circuit configured to sample the steady value at a timing at which the clock pulse is input;
      a first amplifier configured to multiply the sampled steady value by a first predetermined value to generate the first reference value; and
      a second amplifier configured to multiply the sampled steady value by a second predetermined value to generate the second reference value.
Clause 7 (Embodiment 6). The electronic circuitry according to clause 5, wherein
   the steady value is an analog signal, and
   the reference value generator includes:
      an A/D converter configured to convert the steady value into a digital signal in accordance with the control signal;
      a D/A converter configured to convert the steady value converted into the digital signal into an analog signal;
      a first amplifier configured to multiply the steady value converted into the analog signal by a first predetermined value to generate the first reference value; and
      a second amplifier configured to multiply the steady value converted into the analog signal by a second predetermined value to generate the second reference value.
Clause 8 (Embodiment 1). The electronic circuitry according to clause 5, wherein
   the timing detection circuit includes:
      a first comparator configured to compare the integrated value with the first reference value; and
      a second comparator configured to compare the integrated value with the second reference value.
Clause 9 (Embodiment 4). The electronic circuitry according to clause 8, wherein the timing detection circuit further includes: a first delay circuit configured to delay an output value of the first comparator by a first delay time; and a second delay circuit configured to delay an output value of the second comparator by a second delay time.
Clause 10 (Embodiment 2, 3). The electronic circuitry according to clause 8 or 9, wherein
   the timing detection circuit further includes:
      a first edge detector configured to detect either a rising edge or a falling edge of an output value of the first comparator; and
      a second edge detector configured to detect either a rising edge or a falling edge of an output value of the second comparator.
Clause 11 (Embodiment 5). The electronic circuitry according to clause 10, wherein
   the timing detection circuit further includes:
      a first delay circuit configured to delay an output value of the first edge detector by a first delay time; and
      a second delay circuit configured to delay an output value of the second edge detector by a second delay time.
Clause 12 (Embodiment 7). The electronic circuitry according to any one of clauses 1 to 11, wherein
   the arithmetic circuit includes a differentiator configured to output a differential value of the physical quantity, and
   the calculation result is the differential value.
Clause 13 (Embodiment 7). The electronic circuitry according to clause 12, wherein
   the timing detection circuit includes:
      a hysteresis comparator configured to compare the differential value with a third reference value and a fourth reference value;
      a third edge detector configured to detect either a rising edge or a falling edge of an output value of the hysteresis comparator; and
      a fourth edge detector configured to detect the other of the rising edge or the falling edge of the output value of the hysteresis comparator.
Clause 14 (Embodiment 8). The electronic circuitry according to clause 13, wherein
   the timing detection circuit further includes:
      a third delay circuit configured to delay an output value of the third edge detector by a third delay time; and
      a fourth delay circuit configured to delay an output value of the fourth edge detector by a fourth delay time.
Clause 15 (Embodiment 9). The electronic circuitry according to any one of clauses 1 to 14, wherein
   the arithmetic circuit includes a limit amplifier configured to output an amplified value of the physical quantity limited within a predetermined range, and
   the calculation result is the amplified value.
Clause 16 (Embodiment 9). The electronic circuitry according to clause 15, wherein
   the timing detection circuit includes:
      a fifth edge detector configured to detect either a rising edge or a falling edge of the amplified value; and
      a sixth edge detector configured to detect the other of the rising edge or the falling edge of the amplified value.
Clause 17 (Embodiment 10). The electronic circuitry according to clause 16, wherein
   the timing detection circuit further includes:
      a fifth delay circuit configured to delay an output value of the fifth edge detector by a fifth delay time; and
      a sixth delay circuit configured to delay an output value of the sixth edge detector by a sixth delay time.
Clause 18 (Embodiment 11). The electronic circuitry according to any one of clauses 1 to 17, wherein
   the command value of the drive current is a fourth current value at start of turn-off of the switching element, and
   the controller switches the drive current value specified by the command value to the first current value having an absolute value smaller than that of the fourth current value in response to the first timing being detected during a transition period of the turn-off of the switching element.
Clause 19. The electronic circuitry according to clause 18, wherein the controller switches the drive current value specified by the command value to the second current value larger than the first current value in response to the second timing being detected during the transition period of the turn-off of the switching element.
Clause 20 (A power converter). A power converter comprising:
   a half-bridge circuit including two switching elements; and
   a first drive circuit and a second drive circuit configured to respectively control the two switching elements in accordance with a control signal instructing turn-on or turn-off,
   wherein each of the first drive circuit and the second drive circuit includes:
   an arithmetic circuit configured to perform an operation based on a physical quantity corresponding to a time rate of change of an output current of the switching element controlled by the drive circuit;
   a timing detection circuit configured to detect, based on a calculation result of the arithmetic circuit, a first timing and a second timing later than the first timing in a transition period of the turn-on or the turn-off;
   a current supply circuit configured to supply a drive current to the switching element in accordance with a command value of the drive current to be supplied to the switching element; and
   a controller configured to switch a drive current value specified by the command value to a first current value in response to the first timing, and switch the drive current value to a second current value in response to the second timing.
Clause 21 (A power conversion apparatus). A power conversion apparatus comprising three power converters according to clause 20.

1. An electronic circuitry comprising:
an arithmetic circuit configured to perform an operation based on a physical quantity corresponding to a time rate of change of an output current of a switching element controlled in accordance with a control signal instructing turn-on or turn-off;
a timing detection circuit configured to detect, based on a calculation result of the arithmetic circuit, a first timing and a second timing later than the first timing in a transition period of the turn-on or the turn-off;
a current supply circuit configured to supply a drive current to the switching element in accordance with a command value of the drive current to be supplied to the switching element; and
a controller configured to switch a drive current value specified by the command value to a first current value in response to the first timing, and switch the drive current value to a second current value in response to the second timing.

2. The electronic circuitry according to claim 1, wherein
the drive current value specified by the command value is a third current value at start of turn-on of the switching element, and
the controller switches the drive current value specified by the command value to the first current value smaller than the third current value in response to the first timing being detected during a transition period of the turn-on of the switching element.

3. The electronic circuitry according to claim 2, wherein
the controller switches the drive current value specified by the command value to the second current value larger than the first current value in response to the second timing being detected during the transition period of the turn-on of the switching element.

4. The electronic circuitry according to claim 1, wherein
the arithmetic circuit includes an integrator configured to output an integrated value of the physical quantity, and
the calculation result is the integrated value.

5. The electronic circuitry according to claim 4, further comprising a reference value generator configured to generate a first reference value and a second reference value in accordance with a steady value of the integrated value after completion of turn-on of the switching element,
wherein the timing detection circuit detects the first timing based on comparison between the integrated value and the first reference value, and detects the second timing based on comparison between the integrated value and the second reference value.

6. The electronic circuitry according to claim 5, wherein
the steady value is an analog signal, and
the reference value generator includes:
a pulse generator configured to output a clock pulse in accordance with the control signal;
a sample-and-hold circuit configured to sample the steady value at a timing at which the clock pulse is input;
a first amplifier configured to multiply the sampled steady value by a first predetermined value to generate the first reference value; and
a second amplifier configured to multiply the sampled steady value by a second predetermined value to generate the second reference value.

7. The electronic circuitry according to claim 5, wherein
the steady value is an analog signal, and
the reference value generator includes:
an A/D converter configured to convert the steady value into a digital signal in accordance with the control signal;
a D/A converter configured to convert the steady value converted into the digital signal into an analog signal;
a first amplifier configured to multiply the steady value converted into the analog signal by a first predetermined value to generate the first reference value; and
a second amplifier configured to multiply the steady value converted into the analog signal by a second predetermined value to generate the second reference value.

8. The electronic circuitry according to claim 5, wherein
the timing detection circuit includes:
a first comparator configured to compare the integrated value with the first reference value; and
a second comparator configured to compare the integrated value with the second reference value.

9. The electronic circuitry according to claim 8, wherein the timing detection circuit further includes: a first delay circuit configured to delay an output value of the first comparator by a first delay time; and a second delay circuit configured to delay an output value of the second comparator by a second delay time.

10. The electronic circuitry according to claim 8, wherein
the timing detection circuit further includes:
a first edge detector configured to detect either a rising edge or a falling edge of an output value of the first comparator; and
a second edge detector configured to detect either a rising edge or a falling edge of an output value of the second comparator.

11. The electronic circuitry according to claim 10, wherein
the timing detection circuit further includes:
a first delay circuit configured to delay an output value of the first edge detector by a first delay time; and
a second delay circuit configured to delay an output value of the second edge detector by a second delay time.

12. The electronic circuitry according to claim 1, wherein
the arithmetic circuit includes a differentiator configured to output a differential value of the physical quantity, and
the calculation result is the differential value.

13. The electronic circuitry according to claim 12, wherein
the timing detection circuit includes:
a hysteresis comparator configured to compare the differential value with a third reference value and a fourth reference value;
a third edge detector configured to detect either a rising edge or a falling edge of an output value of the hysteresis comparator; and
a fourth edge detector configured to detect the other of the rising edge or the falling edge of the output value of the hysteresis comparator.

14. The electronic circuitry according to claim 13, wherein
the timing detection circuit further includes:
a third delay circuit configured to delay an output value of the third edge detector by a third delay time; and
a fourth delay circuit configured to delay an output value of the fourth edge detector by a fourth delay time.

15. The electronic circuitry according to claim 1, wherein
the arithmetic circuit includes a limit amplifier configured to output an amplified value of the physical quantity limited within a predetermined range, and
the calculation result is the amplified value.

16. The electronic circuitry according to claim 15, wherein
the timing detection circuit includes:
a fifth edge detector configured to detect either a rising edge or a falling edge of the amplified value; and
a sixth edge detector configured to detect the other of the rising edge or the falling edge of the amplified value.

17. The electronic circuitry according to claim 16, wherein
the timing detection circuit further includes:
a fifth delay circuit configured to delay an output value of the fifth edge detector by a fifth delay time; and
a sixth delay circuit configured to delay an output value of the sixth edge detector by a sixth delay time.

18. The electronic circuitry according to claim 1, wherein
the command value of the drive current is a fourth current value at start of turn-off of the switching element, and
the controller switches the drive current value specified by the command value to the first current value having an absolute value smaller than that of the fourth current value in response to the first timing being detected during a transition period of the turn-off of the switching element.

19. The electronic circuitry according to claim 18, wherein
the controller switches the drive current value specified by the command value to the second current value larger than the first current value in response to the second timing being detected during the transition period of the turn-off of the switching element.

20. A power converter comprising:
a half-bridge circuit including two switching elements; and
a first drive circuit and a second drive circuit configured to respectively control the two switching elements in accordance with a control signal instructing turn-on or turn-off,
wherein each of the first drive circuit and the second drive circuit includes:
an arithmetic circuit configured to perform an operation based on a physical quantity corresponding to a time rate of change of an output current of the switching element controlled by the drive circuit;
a timing detection circuit configured to detect, based on a calculation result of the arithmetic circuit, a first timing and a second timing later than the first timing in a transition period of the turn-on or the turn-off;
a current supply circuit configured to supply a drive current to the switching element in accordance with a command value of the drive current to be supplied to the switching element; and
a controller configured to switch a drive current value specified by the command value to a first current value in response to the first timing, and switch the drive current value to a second current value in response to the second timing.

21. A power conversion apparatus comprising three power converters according to claim 20.
